(19) United States
(12) Patent Application Publication
(10) Pub. No.: US 2023/0353899 A1
(43) Pub. Date: Nov. 2, 2023

(54) IMAGING DEVICE AND METHOD OF DRIVING IMAGING DEVICE

(71) Applicant: Panasonic Intellectual Property Management Co., Ltd., Osaka (JP)

(72) Inventor: MASAMI FUNABASHI, Osaka (JP)

(21) Appl. No.: 18/349,199

(22) Filed: Jul. 10, 2023

Related U.S. Application Data
(63) Continuation of application No. PCT/JP2022/000737, filed on Jan. 12, 2022.

(30) Foreign Application Priority Data
Feb. 8, 2021 (JP) 2021-018080

(51) Int. Cl. H04N 25/65; H04N 25/78; H04N 25/77; H04N 25/703

(52) U.S. Cl. CPC H04N 25/65; H04N 25/78; H04N 25/77; H04N 25/703

(57) ABSTRACT

An imaging device includes a semiconductor substrate, a photoelectric conversion layer located above the semiconductor substrate, a first signal detection transistor that includes a first gate electrode above the semiconductor substrate and that outputs a signal corresponding to an electric potential of the first gate electrode, a second signal detection transistor that includes a second gate electrode above the semiconductor substrate and that outputs a signal corresponding to an electric potential of the second gate electrode, a first contact plug in contact with the first gate electrode, and a second contact plug in contact with the second gate electrode. The first gate electrode is electrically connected to the photoelectric conversion layer through the first contact plug. The second gate electrode and the second contact plug are electrically insulated from the photoelectric conversion layer.

### BACKGROUND

### 1. Technical Field

The present disclosure relates to an imaging device and a method of driving an imaging device.

### 2. Description of the Related Art

In the field of imaging devices, there has been known a technique for noise reduction by obtaining a difference between an electric potential corresponding to an amount of signal charges generated by photoelectric conversion in a charge accumulator that accumulates signal charges generated by photoelectric conversion and a reference potential after an operation to reset the signal charges (see, for example, Japanese Patent Nos. 5406473 and 4779054).

### SUMMARY

There has been a demand for imaging devices and the like that can obtain high-quality images with reduced noises. One non-limiting and exemplary embodiment of the present disclosure provides an imaging device and the like which can reduce noises.

In one general aspect, the techniques disclosed here feature an imaging device including: a semiconductor substrate; a photoelectric conversion layer located above the semiconductor substrate; a first transistor that includes a first gate electrode above the semiconductor substrate and that outputs a signal corresponding to an electric potential of the first gate electrode; a second transistor that includes a second gate electrode above the semiconductor substrate and that outputs a signal corresponding to an electric potential of the second gate electrode; a first plug being in contact with the first gate electrode; and a second plug being in contact with the second gate electrode, in which the first gate electrode is electrically connected to the photoelectric conversion layer through the first plug, and the second gate electrode and the second plug are electrically insulated from the photoelectric conversion layer.

The present disclosure can provide an imaging device which reduces noises.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a circuit diagram illustrating an exemplary circuit configuration of an imaging device according to Embodiment 1;

FIG. 2A is a schematic sectional view illustrating sectional structures of an effective pixel and a dummy pixel in the imaging device according to the Embodiment 1;

FIG. 2B is a schematic sectional view illustrating sectional structures of an effective pixel and a dummy pixel according to a modified example of the Embodiment 1;

FIG. 3A is a plan view illustrating an example of a positional relation between a pixel electrode and a gate electrode in each of the effective pixel and the dummy pixel according to the Embodiment 1;

FIG. 3B is a plan view illustrating another example of the positional relation between the pixel electrode and the gate electrode in each of the effective pixel and the dummy pixel according to the Embodiment 1;

FIG. 3C is a plan view illustrating still another example of the positional relation between the pixel electrode and the gate electrode in each of the effective pixel and the dummy pixel according to the Embodiment 1;

FIG. 4 is a schematic circuit diagram of the imaging device according to the Embodiment 1;

FIG. 5A is a circuit diagram of the effective pixel according to the Embodiment 1;

FIG. 5B is a circuit diagram of the dummy pixel according to the Embodiment 1;

FIG. 6 is a diagram illustrating a sequence of a signal readout operation in frames by the imaging device according to the Embodiment 1;

FIG. 7 is a flowchart illustrating an example of a method of driving the imaging device according to the Embodiment 1;

FIG. 8 is a diagram illustrating a sequence of a signal readout operation in one frame by the imaging device according to the Embodiment 1;

FIG. 9 is a schematic circuit diagram of an imaging device according to Embodiment 2;

FIG. 10 is a diagram illustrating a sequence of a signal readout operation of the imaging device according to the Embodiment 2;

FIG. 11 is a schematic circuit diagram of an imaging device according to Embodiment 3;

FIG. 12 is a circuit diagram of a dummy pixel according to the Embodiment 3;

FIG. 13 is a diagram illustrating a sequence of a signal readout operation of the imaging device according to the Embodiment 3;

FIG. 14 is a schematic circuit diagram of an imaging device according to Embodiment 4;

FIG. 15 is a diagram illustrating a sequence of a signal readout operation of the imaging device according to the Embodiment 4;

FIG. 16 is a schematic circuit diagram of an imaging device according to Embodiment 5;

FIG. 17A is a circuit diagram of an effective pixel according to the Embodiment 5;

FIG. 17B is a circuit diagram of a dummy pixel according to the Embodiment 5;

FIG. 18 is a diagram illustrating a sequence of a signal readout operation of the imaging device according to the Embodiment 5;

FIG. 19 is a schematic circuit diagram of an imaging device according to Embodiment 6;

FIG. 20 is a diagram illustrating a sequence of a signal readout operation of the imaging device according to the Embodiment 6;

FIG. 21 is a schematic circuit diagram of an imaging device according to Embodiment 7;

FIG. 22 is a circuit diagram of a dummy pixel according to the Embodiment 7;

FIG. 23 is a diagram illustrating a sequence of a signal readout operation of the imaging device according to the Embodiment 7;

FIG. 24 is a schematic circuit diagram of an imaging device according to Embodiment 8; and

FIG. 25 is a diagram illustrating a sequence of a signal readout operation of the imaging device according to the Embodiment 8.

### DETAILED DESCRIPTIONS

Underlying Knowledge Forming Basis of the Present Disclosure

As mentioned above, there has been the demand for noise reduction in imaging devices. Japanese Patent No. 5406473 discloses a radiation detecting apparatus including a photoelectric conversion element located above a semiconductor substrate. The semiconductor substrate according to Japanese Patent No. 5406473 is provided with a transfer thin film transistor (TFT) for reading out a signal obtained by photoelectric conversion, and a dummy TFT for reading out a dummy signal. A source electrode of the transfer TFT is connected to the photoelectric conversion element whereas a source electrode of the dummy TFT is not connected to the photoelectric conversion element. In the above-described configuration, an effect of noises that are superimposed on circuit wiring for readout is reduced by obtaining a difference between the signal obtained by photoelectric conversion and the dummy signal being a dark output signal.

However, in the configuration disclosed in Japanese Patent No. 5406473, the source electrode of the dummy TFT is either in a floating state of being electrically connected to nowhere or in a state of being connected to a fixed electric potential irrelevant to a photoelectric conversion signal. For this reason, noises not correlated with the noises to be superimposed on the signal obtained from the transfer TFT may be superimposed on the dummy signal obtained from the dummy TFT. In this case, it is difficult to remove a noise component superimposed only on the signal obtained by photoelectric conversion or a noise component superimposed only on the dummy signal even by obtaining the difference between the signal obtained by photoelectric conversion and the dummy signal.

Japanese Patent No. 4779054 discloses an imaging device including an effective pixel that performs photoelectric conversion and a dummy pixel that does not perform the photoelectric conversion. In the imaging device of Japanese Patent No. 4779054, a signal readout circuit in the dummy pixel that does not perform the photoelectric conversion is not electrically connected to a photoelectric conversion element but is connected to a capacitor instead. In the above-described configuration, an effect of noises is reduced by obtaining a difference between an output signal from the effective pixel obtained by the photoelectric conversion and an output signal from the dummy pixel.

However, a circuit configuration of the effective pixel is significantly different from that of the dummy pixel. In addition, each dummy pixel is disposed at a peripheral part of an effective pixel region where the effective pixels are arranged. In other words, the dummy pixels and the effective pixels are physically distant from one another. As a consequence, a noise component to be superimposed on the effective pixel does not precisely coincide with a noise component to be superimposed on the dummy pixel. Accordingly, it is difficult to sufficiently reduce noises even by obtaining the difference between these signals.

Meanwhile, in the imaging device of a laminated type including the photoelectric converter used in the photoelectric conversion layer located above the semiconductor substrate as in the above-mentioned related art, noises are removed by subtracting a signal corresponding to an electric potential at the charge accumulator after resetting the charge accumulator that accumulates signal charges from a signal corresponding to an electric potential at the charge accumulator that accumulates the signal charges obtained by the photoelectric conversion. However, the inventors of the present disclosure have found out that the aforementioned method of removing noises cannot sufficiently remove the noises in some cases.

To be more precise, the electric potential at the charge accumulator that accumulates the signal charges in a certain frame represents an electric potential as a result of accumulating the signal charges from a state of resetting the electric potential of the charge accumulator one frame earlier than the relevant frame. On the other hand, the electric potential at the charge accumulator after resetting the electric potential at the charge accumulator that accumulates the signal charges in the relevant frame may be different from the electric potential in the case of resetting the electric potential at the charge accumulator one frame earlier than the relevant frame. Accordingly, there may be a case where the noises cannot be sufficiently reduced even by subtracting the signal corresponding to the electric potential at the charge accumulator after resetting the electric potential at the charge accumulator that accumulates the signal charges in the relevant frame from the signal corresponding to the electric potential at the charge accumulator that accumulates the signal charges in the relevant frame. The Japanese Patent Nos. 5406473 and 4779054 do not disclose this problem, and an effective method for reducing the noises is therefore requested.

Given the circumstances, it is an object of the present disclosure to provide an imaging device that can effectively reduce noises.

An imaging device according to an aspect of the present disclosure includes: a semiconductor substrate; a photoelectric conversion layer located above the semiconductor substrate; a first transistor that includes a first gate electrode above the semiconductor substrate, and amplifies a signal corresponding to an electric potential at the first gate electrode to output the amplified signal; a second transistor that includes a second gate electrode above the semiconductor substrate, and amplifies a signal corresponding to an electric potential at the second gate electrode to output the amplified signal; a first plug being in contact with the first gate electrode; and a second plug being in contact with the second gate electrode, in which the first gate electrode is electrically connected to the photoelectric conversion layer through the first plug, and the second gate electrode and the second plug are electrically insulated from the photoelectric conversion layer.

Accordingly, it is possible to reduce noises by using the signal outputted from the first transistor and the signal outputted from the second transistor. To be more precise, the signal outputted from the second transistor, which is not affected by the photoelectric conversion in the photoelectric conversion layer, can be used as the signal corresponding to the electric potential when the electric potential at the first gate electrode is reset. Thus, the noises in the signal outputted from the first transistor can be removed at high accuracy.

For example, the imaging device may further includes: a first pixel electrode electrically connected to the photoelectric conversion layer, in which the first plug may be electrically connected to the photoelectric conversion layer through the first pixel electrode.

Accordingly, the signal charges generated in the photoelectric conversion layer are collected by the first pixel electrode, so that the first transistor can output the signal corresponding to the amount of signal charges collected by the first pixel electrode.

For example, the first gate electrode and the second gate electrode may overlap the first pixel electrode in plan view.

Accordingly, the first pixel electrode spreads to a position of the second gate electrode in plan view. Thus, it is possible to increase the area of the first pixel electrode and to increase the signal outputted from the first transistor.

For example, the imaging device may further includes: a second pixel electrode electrically connected to the photoelectric conversion layer, in which the second gate electrode and the second plug may be electrically insulated from the second pixel electrode, the first gate electrode may overlap the first pixel electrode in plan view, and the second gate electrode may overlap the second pixel electrode in plan view.

Accordingly, a structure around the first transistor and a structure around the second transistor involve less differences in manufacturing processes. Thus, the degrees of the noises to be superimposed on the electric potential at the first gate electrode and on the electric potential at the second gate electrode are more likely to be equalized.

For example, the imaging device may further includes: at least one plug electrically connected to the second plug, in which the at least one plug may include a third plug that is located closest to the photoelectric conversion layer out of the at least one plug, and a distance from a first surface of the third plug, the first surface being located closest to the photoelectric conversion layer, to the photoelectric conversion layer may be smaller than a distance from the first surface to the semiconductor substrate.

Accordingly, it is possible to make wiring structures of the plugs and the like to be connected to the first gate electrode similar to wiring structures of the plugs and the like to be connected to the second gate electrode by connecting the second gate electrode to the plug located at a position close to the photoelectric conversion layer. Thus, the degrees of the noises to be superimposed on the electric potential at the first gate electrode and on the electric potential at the second gate electrode are more likely to be equalized.

For example, a length of the first plug may be equal to a length of the second plug.

Accordingly, it is possible to make the wiring structures of the plugs and the like to be connected to the first gate electrode similar to the wiring structures of the plugs and the like to be connected to the second gate electrode. Thus, the degrees of the noises to be superimposed on the electric potential at the first gate electrode and on the electric potential at the second gate electrode are more likely to be equalized.

For example, the imaging device may further includes: a third transistor that includes a third gate electrode above the semiconductor substrate, and amplifies a signal corresponding to an electric potential at the third gate electrode to output the amplified signal; a fourth transistor that includes a fourth gate electrode above the semiconductor substrate, and amplifies a signal corresponding to an electric potential at the fourth gate electrode to output the amplified signal; a fourth plug being in contact with the third gate electrode; and a fifth plug being in contact with the fourth gate electrode, in which the third gate electrode may be electrically connected to the photoelectric conversion layer through the fourth plug, the fourth gate electrode and the fifth plug may be electrically insulated from the photoelectric conversion layer, and the second gate electrode may be electrically connected to the fourth gate electrode.

Accordingly, it is possible to reduce a variation between the electric potential at the second gate electrode and the electric potential at the fourth gate electrode by averaging the electric potentials at the second gate electrode and the fourth gate electrode which are electrically insulated from the photoelectric conversion layer.

For example, the imaging device may further include: a first switch provided between the second gate electrode and the fourth gate electrode.

Accordingly, it is possible to switch between a mode to average the electric potentials at the second gate electrode and the fourth gate electrode and a mode to separate the electric potentials at the second gate electrode and the fourth gate electrode from each other. Thus, the electric potentials at the second gate electrode and the fourth gate electrode can be averaged only at required timing.

For example, the imaging device may further include: a first signal line to which the signal outputted from the first transistor and the signal outputted from the second transistor are inputted.

Accordingly, it is possible to average the signal line to which the first transistor and the second transistor output signals, and thus to downsize the imaging device.

A method of driving an imaging device according to another aspect of the present disclosure is a method of driving an imaging device, which is provided with an effective pixel including a charge accumulator to accumulate electric charges obtained by photoelectric conversion by a photoelectric conversion layer, and outputs a signal based on an amount of the electric charges accumulated in the charge accumulator, the method including: resetting an electric potential at the charge accumulator; accumulating the electric charges obtained by the photoelectric conversion by the photoelectric conversion layer after the resetting in the charge accumulator that is reset in the resetting; reading out a first signal corresponding to the electric potential at the charge accumulator that is reset in the resetting; reading out a second signal corresponding to the electric potential at the charge accumulator after accumulating the electric charges in the accumulating; and outputting a third signal obtaining by subtracting the first signal from the second signal.

Accordingly, subtraction of the first signal from the second signal makes it possible to output the third signal that deals with a change in electric potential at the charge accumulator before and after accumulating the electric charges in the accumulating. Thus, the third signal is outputted as the photoelectric conversion signal with reduced noises.

A method of driving an imaging device according to still another aspect of the present disclosure is a method of driving an imaging device, which is provided with an effective pixel including a charge accumulator to accumulate electric charges obtained by photoelectric conversion by a photoelectric conversion layer, and a dummy pixel including a dummy charge accumulator being insulated from the photoelectric conversion layer, the method including: resetting an electric potential at the charge accumulator and an electric potential at the dummy charge accumulator; accumulating the electric charges obtained by the photoelectric conversion by the photoelectric conversion layer after the resetting in the charge accumulator that is reset in the resetting; reading out a first signal corresponding to the electric potential at the dummy charge accumulator that is reset in the resetting; reading out a second signal corresponding to the electric potential at the charge accumulator after accumulating the electric charges in the accumulating; and outputting a third signal obtaining by subtracting the first signal from the second signal.

Accordingly, even when crosstalk noises and the like that are not related to the electric charges generated by the photoelectric conversion in the photoelectric conversion layer are superimposed on the charge accumulator of the effective pixel and the dummy charge accumulator of the dummy pixel in the accumulating, it is possible to remove an adverse effect of the crosstalk noises and the like from the third signal by using the signal corresponding to the electric potential at the dummy charge accumulator as the first signal.

Now, embodiments of the present disclosure will be described below with reference to the drawings. Each of the embodiments described below represents either a comprehensive or specific example. Numerical values, shapes, materials, constituents, layouts and modes of connection of the constituents, steps, the orders of the steps, and the like depicted in the following embodiments are mere examples and are not intended to restrict the scope of the present disclosure. Various modes described in the present specification can be carried out in combination unless such a combination leads to contradiction. Meanwhile, of the constituents in the following embodiments, a constituent not defined in an independent claim will be described as an optional constituent. In the meantime, the respective drawings are not always illustrated precisely. Accordingly, scales and other factors do not always coincide with one another in the drawings, for example. It is to be also noted that the constituents having substantially the same function may be denoted by common reference signs in the following description, and overlapping explanations thereof may be omitted as appropriate.

In the present specification, terms that represent relations between elements, terms that represent shapes of the elements, and numerical ranges are not expressions that only represent precise meanings but are rather expressions that encompass virtually equivalent ranges with allowances of several percent, for example.

In the present specification, terms “above” and “below” do not represent an upward direction (vertically upward) or a downward direction (vertically downward) in terms only of absolute spatial recognition, but are used as terms to be defined depending on a relative positional relation based on the order of lamination in a laminated structure. To be more precise, a light receiving side of an imaging device will be regarded as “above” while an opposite side of the light receiving side will be regarded as “below”. Here, the terms “above”, “below”, and the like are used solely for the purpose of designating relative locations between components and are not intended to restrict a posture when the imaging device is in use. In addition, the terms “above” and “below” are used not only in a case where there are two constituents disposed with an interval therebetween and another constituent is present between these two constituents, but also in a case where two constituents are disposed close to each other and the two constituents are in contact with each other as a consequence.

Moreover, in the present specification, the term “connection” means electrical connection unless otherwise stated.

### Embodiment 1

### Circuit Configuration of Imaging Device

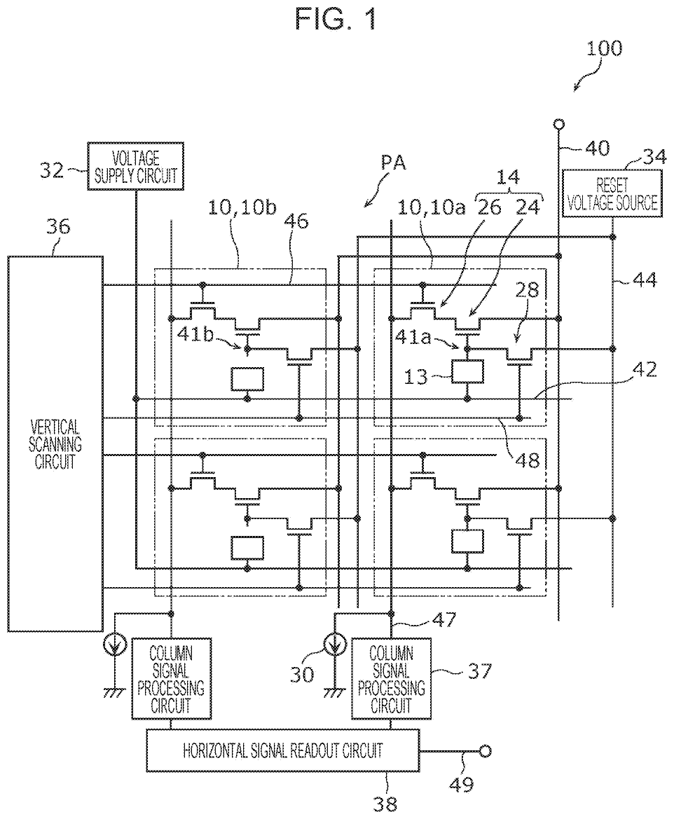

First, a circuit configuration of an imaging device according to the present embodiment will be described with reference to FIG. 1.

FIG. 1 is a circuit diagram illustrating an exemplary circuit configuration of an imaging device according to the present embodiment. An imaging device 100 illustrated in FIG. 1 includes peripheral circuits, and a pixel array PA provided with pixels 10 that are two-dimensionally arranged. The peripheral circuits include a constant-current source 30, a voltage supply circuit 32, a reset voltage source 34, a vertical scanning circuit 36, a column signal processing circuit 37, and a horizontal signal readout circuit 38. The peripheral circuits may include a voltage source not illustrated in FIG. 1 or a circuit such as a control circuit other than those mentioned above.

The pixels 10 include effective pixels 10a and dummy pixels 10b. FIG. 1 schematically illustrates an example in which the pixels 10 are arranged in a matrix of two rows and two columns. In the example illustrated in FIG. 1, two pixels on a right side are the effective pixels 10a and two pixels on a left side are the dummy pixels 10b. Each effective pixel 10a and the corresponding dummy pixel 10b form a pair of pixels 10, for example. Hence, the imaging device 100 includes pairs of the pixels 10. The numbers of the effective pixels 10a and the dummy pixels 10b in the imaging device 100 as well as layouts thereof are not limited to the example illustrated in FIG. 1. For instance, the imaging device 100 may be a line sensor in which the effective pixels 10a and the dummy pixels 10b are alternately arranged in a line. Alternatively, the imaging device 100 may be provided with only one effective pixel 10a and only one dummy pixel 10b. In the following description, a configuration that is common to the effective pixel 10a and the dummy pixel 10b may be explained while referring to the effective pixel 10a and the dummy pixel 10b collectively as the pixels 10. Configurations that are different between the effective pixel 10a and the dummy pixel 10b will be separately explained in terms of the effective pixel 10a and the dummy pixel 10b.

Each pixel 10 includes a photoelectric converter 13 and a signal detection circuit 14. The photoelectric converter 13 receives incident light and generates a signal. The entire photoelectric converter 13 does not always have to be an independent element for each pixel 10. For example, a portion of the photoelectric converter 13 may extend across two or more pixels 10. The signal detection circuit 14 is a circuit for detecting the signal generated by the photoelectric converter 13. In this example, the signal detection circuit 14 includes a signal detection transistor 24 and an address transistor 26. Each of the signal detection transistor 24 and the address transistor 26 is a field effect transistor (FET), for example. Here, an N-channel metal oxide semiconductor field effect transistor (MOSFET) is illustrated as an example of each of the signal detection transistor 24 and the address transistor 26. Each of the signal detection transistor 24, the address transistor 26, and more transistors to be described later such as a reset transistor 28 and a bandwidth control transistor 81 includes a control terminal, an input terminal, and an output terminal. The control terminal is a gate electrode, for example. The input terminal is one of a drain and a source. Here, the input terminal is the drain, for example. The output terminal is the other one of the drain and the source. Here, the output terminal is the source, for example.

As schematically illustrated in FIG. 1, the control terminal being the gate electrode of the signal detection transistor 24 in the effective pixel 10a is electrically connected to the photoelectric converter 13. The control terminal being the gate electrode of the signal detection transistor 24 in the dummy pixel 10b is not electrically connected to the photoelectric converter 13. Accordingly, in the effective pixel 10a, signal charges generated by the photoelectric converter 13 are accumulated in a charge accumulator 41a located between the gate electrode of the signal detection transistor 24 and the photoelectric converter 13. On the other hand, in the dummy pixel 10b, signal charges generated by the photoelectric converter 13 are not accumulated in a charge accumulator 41b connected to the gate electrode of the signal detection transistor 24. In the meantime, the charge accumulator 41a and the charge accumulator 41b also accumulate electric charges generated when resetting electric potentials at the charge accumulator 41a and the charge accumulator 41b, and electric charges that are generated by noises and the like from the peripheral circuits and the like.

Here, the signal charges are either holes or electrons. The charge accumulator 41b is an example of a dummy charge accumulator. Each of the charge accumulator 41a and the charge accumulator 41b includes a node to be connected to the gate electrode of the corresponding signal detection transistor 24, for example. Each of the charge accumulator 41a and the charge accumulator 41b may also be referred to as a “floating diffusion node”. Details of the structure of the photoelectric converter 13 will be described later.

The photoelectric converter 13 of each pixel 10 is further connected to a bias control line 42 and a predetermined voltage is applied to the photoelectric converter 13. In the configuration exemplarily illustrated in FIG. 1, each bias control line 42 is connected to the voltage supply circuit 32.

Each pixel 10 is connected to a power supply line 40 that feeds a power supply voltage VDD. As illustrated in FIG. 1, the input terminal of the signal detection transistor 24 is connected to the power supply line 40. The power supply line 40 functions as a source follower power supply, whereby the signal detection transistor 24 amplifies and outputs the electric potential at the charge accumulator 41a. The signal detection transistor 24 of the effective pixel 10a is an example of a first transistor and the signal detection transistor 24 of the dummy pixel 10b is an example of a second transistor.

The input terminal of the address transistor 26 is connected to the output terminal of the signal detection transistor 24. The output terminal of the address transistor 26 is connected to one of vertical signal lines 47 arranged corresponding to respective rows of the pixel arrays PA. The control terminal of the address transistor 26 is connected to an address control line 46. The output from the signal detection transistor 24 can be selectively read out to the corresponding vertical signal line 47 by controlling an electric potential at the address control line 46.

In the example illustrated in FIG. 1, the address control line 46 is connected to the vertical scanning circuit 36. The vertical scanning circuit 36 is also referred to as a “row scanning circuit”. The vertical scanning circuit 36 applies a predetermined voltage to the address control line 46, thereby selecting the pixels 10 arranged on each row on the row basis. In this way, the vertical scanning circuit 36 executes readout of the signals from the selected pixels 10 and resetting of the charge accumulators 41a and the charge accumulators 41b thereof. The vertical scanning circuit 36 outputs various control signals of pulse voltages such as a scan signal SEL to be described later.

Each vertical signal line 47 is a main signal line that transfers pixel signals from the pixel array PA to the peripheral circuits. The column signal processing circuit 37 and the constant-current source 30 are connected to each vertical signal line 47. The column signal processing circuit 37 is also referred to as a “row signal accumulation circuit”. The column signal processing circuit 37 carries out noise suppression signal processing as typified by correlated double sampling, analog-digital conversion (AD conversion), and the like. Details of the processing to be carried out by the column signal processing circuit 37 will be described later. As illustrated in FIG. 1, the column signal processing circuit 37 and the constant-current source 30 are provided corresponding to each row of pixels 10 in the pixel array PA. The horizontal signal readout circuit 38 is connected to these column signal processing circuits 37. The horizontal signal readout circuit is also referred to as a “column scanning circuit”. The horizontal signal readout circuit 38 sequentially reads signals out of the column signal processing circuits 37 and transfers the signals to a horizontal common signal line 49.

In the configuration illustrated as an example in FIG. 1, each pixel 10 includes the reset transistor 28. The reset transistor 28 is a field effect transistor as with the signal detection transistor 24 and the address transistor 26, for example. The following description will discuss an example of adopting an N-channel MOSFET as the reset transistor 28 unless otherwise stated. As illustrated in FIG. 1, the reset transistor 28 is connected between a reset voltage line 44 that feeds a reset voltage Vrst and any of the charge accumulator 41a and the charge accumulator 41b. The control terminal of the reset transistor 28 is connected to a reset control line 48. The electric potential at the charge accumulator 41a or the charge accumulator 41b can be reset to the reset voltage Vrst by controlling the electric potential at the reset control line 48. In this example, the reset control line 48 is connected to the vertical scanning circuit 36. Accordingly, the pixels 10 arranged on each row can be reset on the row basis by causing the vertical scanning circuit 36 to apply a predetermined voltage to the reset control line 48.

In this example, the reset voltage line 44 that feeds the reset voltage Vrst to the reset transistor 28 is connected to the reset voltage source 34. The reset voltage source is also referred to as a “reset voltage supply circuit”. The reset voltage source 34 only needs to have such a configuration that can feed the predetermined reset voltage Vrst to the reset voltage line 44 when the imaging device 100 is in operation, and is not limited to a specific power supply circuit as with the above-described voltage supply circuit 32. The voltage supply circuit 32 and the reset voltage source 34 may each be a portion of a single voltage supply circuit or may be separate and independent voltage supply circuits. Here, one or both of the voltage supply circuit 32 and the reset voltage source 34 may be a portion of the vertical scanning circuit 36. Alternatively, a control voltage from the voltage supply circuit 32 and/or the reset voltage Vrst from the reset voltage source 34 may be supplied to each pixel 10 through the vertical scanning circuit 36.

It is also possible to use the power supply voltage VDD from the signal detection circuit 14 as the reset voltage Vrst. In this case, it is possible to average the voltage supply circuit (not illustrated in FIG. 1) to feed the power supply voltage to each pixel 10 and the reset voltage source 34. Moreover, it is possible to average the power supply line 40 and the reset voltage line 44, thereby simplifying the wiring in the pixel array PA.

Nonetheless, the imaging device 100 can be controlled more flexibly by setting the reset voltage Vrst to a different voltage from the power supply voltage VDD from the signal detection circuit 14.

### Device Structures of Pixels

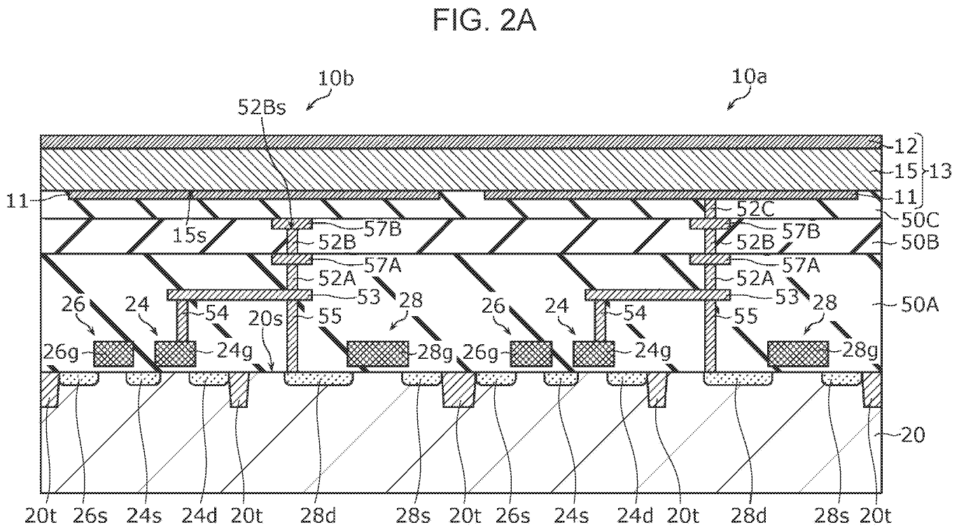

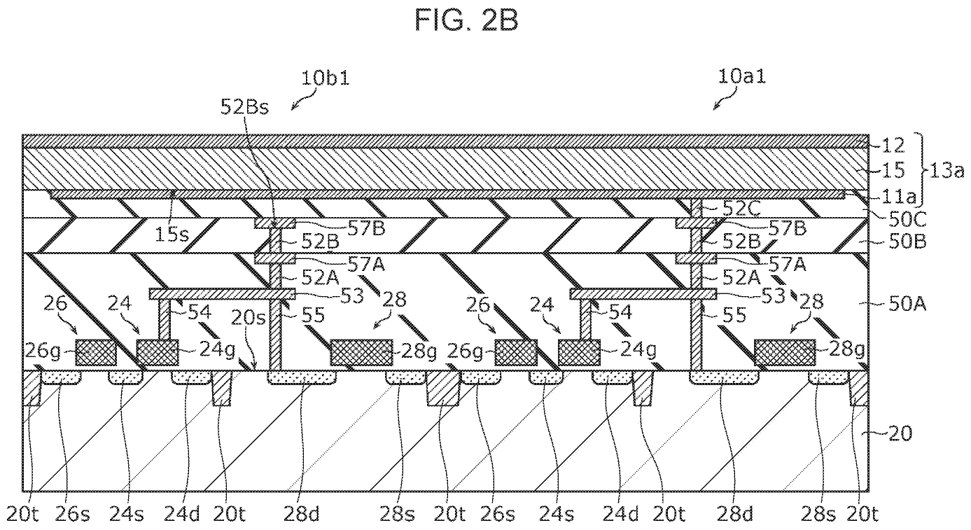

Next, sectional structures of the effective pixel 10a and the dummy pixel 10b in the imaging device 100 according to the present embodiment will be described with reference to FIG. 2A.

FIG. 2A is a schematic sectional view illustrating sectional structures of the effective pixel 10a and the dummy pixel 10b in the imaging device 100 according to the present embodiment. The effective pixel 10a and the dummy pixel 10b are arranged adjacent to each other, for example. The effective pixel 10a will be described to begin with, and different features of the dummy pixel 10b therefrom will be described later. The effective pixel 10a in the imaging device 100 includes a semiconductor substrate 20 containing silicon, pixel electrodes 11 located above the semiconductor substrate 20 and electrically connected to the semiconductor substrate 20, respectively, a counter electrode 12 located above the pixel electrodes 11, and a photoelectric conversion layer 15 located between the set of pixel electrodes 11 and the counter electrode 12.

In the configuration illustrated as an example in FIG. 2A, the signal detection transistor 24, the address transistor 26, and the reset transistor 28 mentioned above are formed in the semiconductor substrate 20. The semiconductor substrate 20 is not limited to a substrate formed entirely from semiconductor. The semiconductor substrate 20 may be an insulative substrate provided with a semiconductor layer on a surface to which a photoconductive region is provided, for example. A semiconductor substrate containing silicon is used as the semiconductor substrate 20. An example of using a P-type silicon (Si) substrate as the semiconductor substrate 20 will be described herein.

The semiconductor substrate 20 includes impurity regions 26s, 24s, 24d, 28d, and 28s and element insulation regions 20t for establishing electrical insulation among the respective pixels 10. Here, the impurity regions 26s, 24s, 24d, 28d, and 28s are N-type regions. Meanwhile, the element insulation region 20t is also provided between the impurity region 24d and the impurity region 28d. Each element insulation region 20t is formed by carrying out ion implantation of an acceptor under predetermined conditions of implantation, for example.

The impurity regions 26s, 24s, 24d, 28d, and 28s are diffused layers of impurities formed in the semiconductor substrate 20, for example. As schematically illustrated in FIG. 2A, the signal detection transistor 24 includes the impurity region 24s, the impurity region 24d, and a gate electrode 24g. The gate electrode 24g of the effective pixel 10a is an example of a first gate electrode. The signal detection transistor 24 amplifies a signal corresponding to an electric potential at the gate electrode 24g to output the amplified signal. The gate electrode 24g is provided above the semiconductor substrate 20 through the intermediary of a portion of an interlayer insulating layer 50A. The gate electrode 24g is formed by using a conductive material. The conductive material is polycrystalline silicon provided with conductivity by being doped with an impurity, for example. However, the conductive material may be a metal material instead. The impurity region 24s functions as a source region of the signal detection transistor 24, for example. The impurity region 24d functions as a drain region of the signal detection transistor 24, for example. A channel region of the signal detection transistor 24 is formed between the impurity region 24s and the impurity region 24d.

Likewise, the address transistor 26 includes the impurity region 26s, the impurity region 24s, and a gate electrode 26g. The gate electrode 26g is formed by using a conductive material. The conductive material is polycrystalline silicon provided with conductivity by being doped with an impurity, for example. However, the conductive material may be a metal material instead. The gate electrode 26g is connected to the address control line 46 which is not illustrated in FIG. 2A. In this example, the signal detection transistor 24 and the address transistor 26 share the impurity region 24s, thereby being electrically connected to each other. The impurity region 24s functions as a drain region of the address transistor 26, for example. The impurity region 26s functions as a source region of the address transistor 26, for example. The impurity region 26s is connected to the vertical signal line 47 which is not illustrated in FIG. 2A. Here, the impurity region 24s does not have to be shared by the signal detection transistor 24 and the address transistor 26. For instance, the source region of the signal detection transistor 24 and the drain region of the address transistor 26 may be separated from each other in the semiconductor substrate 20 and electrically connected to each other through a wiring layer provided in the interlayer insulating layer 50A.

The reset transistor 28 includes the impurity regions 28d and 28s, and a gate electrode 28g. The gate electrode 28g is formed by using a conductive material, for instance. The conductive material is polycrystalline silicon provided with conductivity by being doped with an impurity, for example. However, the conductive material may be a metal material instead. The gate electrode 28g is connected to the reset control line 48 which is not illustrated in FIG. 2A. The impurity region 28s functions as a source region of the reset transistor 28, for example. The impurity region 28s is connected to the reset voltage line 44 which is not illustrated in FIG. 2A. The impurity region 28d functions as a drain region of the reset transistor 28, for example.

The interlayer insulating layer 50A is disposed above the semiconductor substrate 20 in such a way as to cover the signal detection transistor 24, the address transistor 26, and the reset transistor 28. An interlayer insulating layer 50B and an interlayer insulating layer 50C are laminated above the interlayer insulating layer 50A in this order from below. Each of the interlayer insulating layers 50A, 50B, and 50C is formed from an insulating material such as silicon dioxide. Although illustration is omitted, wiring layers are provided in each of the interlayer insulating layers 50A, 50B, and 50C. Each wiring layer is formed from a metal such as copper. The wiring layer may include the signal lines such as the above-mentioned vertical signal line 47, or the power supply line as a part of the layer, for example. The number of layers of each of the interlayer insulating layers 50A, 50B, and 50C and the number of layers of the wiring layers to be provided in each of the interlayer insulating layers 50A, 50B, and 50C may be set to any numbers and are not limited to the example illustrated in FIG. 2A.

In the configuration illustrated in FIG. 2A, the effective pixel 10a includes a line 57A, a plug 52A, a line 53, a contact plug 54, and a contact plug 55, which are provided in the interlayer insulating layer 50A. The contact plug 54 of the effective pixel 10a is an example of a first plug. The contact plug 54 is in contact with the gate electrode 24g and the line 53, thereby electrically connecting the gate electrode 24g to the line 53. The contact plug 55 is in contact with the impurity region 28d and the line 53, thereby electrically connecting the impurity region 28d to the line 53. The plug 52A is in contact with the line 53 and the line 57A, thereby electrically connecting the line 53 to the line 57A.

The effective pixel 10a also includes a plug 52B and a line 57B which are provided in the interlayer insulating layer 50B. The plug 52B is in contact with the line 57A and the line 57B, thereby electrically connecting the line 57A to the line 57B.

Moreover, the effective pixel 10a includes a plug 52C provided in the interlayer insulating layer 50C. The plug 52C is in contact with the line 57B and pixel electrode 11, thereby electrically connecting the line 57B to the pixel electrode 11. In this way, the line 53 is electrically connected to the pixel electrode 11, for example. The lines 57A, 57B, and 53 may be part of the wiring layer. Each of the plug 52C, the line 57B, the plug 52B, the line 57A, the plug 52A, the line 53, the contact plug 54, and the contact plug 55 is formed by using a conductive material. For example, each of the plug 52C, the line 57B, the plug 52B, the line 57A, the plug 52A, and the line 53 is formed from a metal such as copper. Each of the contact plugs 54 and 55 is formed from polycrystalline silicon provided with conductivity by being doped with an impurity, for example. Here, the plug 52C, the line 57B, the plug 52B, the line 57A, the plug 52A, the line 53, the contact plug 54, and the contact plug 55 may be formed by using the same material or formed by using different materials from one another.

In the effective pixel 10a, the plug 52C, the line 57B, the plug 52B, the line 57A, the plug 52A, the line 53, and the contact plug 54 constitute at least part of the charge accumulator 41a located between the signal detection transistor 24 and the photoelectric converter 13 illustrated in FIG. 1. In the configuration of the effective pixel 10a illustrated as an example in FIG. 2A, the gate electrode 24g of the signal detection transistor 24, the plug 52C, the line 57B, the plug 52B, the line 57A, the plug 52A, the line 53, the contact plug 54, the contact plug 55, and the impurity region 28d serving as one of the source region and the drain region of the reset transistor 28 function as charge accumulating regions that accumulate the signal charges collected by the pixel electrode 11 of the photoelectric converter 13.

The pixel electrode 11 of the photoelectric converter 13 is electrically connected to the gate electrode 24g of the signal detection transistor 24 through the plug 52C, the line 57B, the plug 52B, the line 57A, the plug 52A, the line 53, and the contact plug 54. In other words, the gate electrode 24g of the signal detection transistor 24 is electrically connected to the photoelectric conversion layer 15 through the pixel electrode 11, the plug 52C, the line 57B, the plug 52B, the line 57A, the plug 52A, the line 53, and the contact plug 54. Accordingly, the contact plug 54 is electrically connected to the photoelectric conversion layer 15 through the pixel electrode 11. Meanwhile, the pixel electrode 11 is also electrically connected to the impurity region 28d through the plug 52C, the line 57B, the plug 52B, the line 57A, the plug 52A, the line 53, and the contact plug 55. The pixel electrode 11 of the effective pixel 10a is an example of a first pixel electrode. In the effective pixel 10a, the gate electrode 24g overlaps the pixel electrode 11 in plan view.

As a consequence of collection of the signal charges by the pixel electrode 11, a voltage corresponding to an amount of the signal charges accumulated in the charge accumulator 41a is applied to the gate electrode 24g of the signal detection transistor 24. The signal detection transistor 24 amplifies this voltage to output the amplified voltage. The voltage amplified by the signal detection transistor 24 is selectively read out as a signal voltage through the address transistor 26.

The photoelectric converter 13 is provided across the pixels 10, namely, the effective pixel 10a and the dummy pixel 10b. The photoelectric converter 13 includes the pixel electrodes 11, the counter electrode 12, and the photoelectric conversion layer 15 disposed between the pixel electrodes 11 and the counter electrode 12. In the present embodiment, the counter electrode 12, the photoelectric conversion layer 15, and the pixel electrodes 11 are arranged in this order from a light incident side of the imaging device 100.

The photoelectric converter 13 may further include other elements such as an electron block layer and a hole block layer.

In the example illustrated in FIG. 2A, the counter electrode 12 and the photoelectric conversion layer 15 are formed across the pixels 10. Each of the pixel electrodes 11 is provided to the corresponding pixel 10. One pixel electrode 11 is spatially separated from another pixel electrode 11 for an adjacent different pixel 10, thereby being electrically insulated from the pixel electrode 11 of the different pixel 10. Here, at least one of the counter electrode 12 and the photoelectric conversion layer 15 may be provided separately for each pixel 10. Alternatively, a common pixel electrode may be provided across the effective pixel 10a and the dummy pixel 10b as described later.

The pixel electrode 11 is an electrode that is electrically connected to the photoelectric conversion layer 15 and configured to read out the signal charges generated by the photoelectric converter 13. The pixel electrode 11 of the effective pixel 10a is electrically connected to the gate electrode 24g of the signal detection transistor 24 and to the impurity region 28d. The pixel electrode 11 is formed by using a conductive material.

The counter electrode 12 is a transparent electrode formed from a transparent conductive material, for example. The counter electrode 12 is disposed on the light incident side of the photoelectric conversion layer 15. The voltage supply circuit 32 illustrated in FIG. 1 is connected to the counter electrode 12. By causing the voltage supply circuit 32 to control an electric potential at the counter electrode 12 relative to an electric potential at the pixel electrode 11, the pixel electrode 11 can collect any of holes and electrons out of hole-electron pairs generated in the photoelectric conversion layer 15 as the signal charges. When the holes are used as the signal charges, for instance, the pixel electrode 11 can selectively collect the holes by setting the electric potential at the counter electrode 12 higher than that at the pixel electrode 11.

The photoelectric conversion layer 15 is a layer that absorbs photons and generates photocharges serving as the signal charges. To be more precise, the photoelectric conversion layer 15 receives the incident light and generates the hole-electron pairs. In other words, the signal charges are any of the holes and the electrons. When the holes are used as the signal charges, for instance, the holes are collected by the pixel electrode 11. The electrons that are the electric charges of the reverse polarity are collected by the counter electrode 12. The photoelectric conversion layer 15 is located above the semiconductor substrate 20. The photoelectric conversion layer 15 is composed of a photoelectric convertible material and is formed from an organic semiconductor material, for example. The photoelectric conversion layer 15 may be formed from an inorganic semiconductor material instead.

Next, a configuration of the dummy pixel 10b will be described. The dummy pixel 10b is different from the effective pixel 10a in that the plug 52C is not included in the interlayer insulating layer 50C. Accordingly, in the dummy pixel 10b, the pixel electrode 11 of the photoelectric converter 13 is not electrically connected to the gate electrode 24g of the signal detection transistor 24 or the contact plug 54. In other words, in the dummy pixel 10b, the gate electrode 24g and the contact plug 54 are electrically insulated from the photoelectric conversion layer 15 and the pixel electrode 11 by using the interlayer insulating layer 50C. The gate electrode 24g of the dummy pixel 10b is an example of a second gate electrode and the contact plug 54 of the dummy pixel 10b is an example of a second plug. Meanwhile, the pixel electrode 11 of the dummy pixel 10b is an example of a second pixel electrode. In the dummy pixel 10b, the gate electrode 24g overlaps the pixel electrode 11 in plan view.

The effective pixel 10a and the dummy pixel 10b may have the same configuration, for example, except that the effective pixel 10a includes the charge accumulator 41a electrically connected to the photoelectric converter 13 whereas the dummy pixel 10b includes the charge accumulator 41b that is not electrically connected to the photoelectric converter 13. The configuration of the dummy pixel 10b may be the same as the configuration of the effective pixel 10a except that the dummy pixel 10b does not include the plug 52C, for example. Accordingly, the contact plug 54 of the effective pixel 10a and the contact plug 54 of the dummy pixel 10b have the same shape and a length of the contact plug 54 of the effective pixel 10a is equal to a length of the contact plug 54 of the dummy pixel 10b, for example. Moreover, a height from the semiconductor substrate 20 where the contact plug 54 of the effective pixel 10a is located is equal to a height from the semiconductor substrate 20 where the contact plug 54 of the dummy pixel 10b is located. Thus, a parasitic capacitance of the contact plug 54 and peripheral lines of effective pixel 10a is equal to a parasitic capacitance of the contact plug 54 and peripheral lines of the dummy pixel 10b. As a consequence, it is possible to reduce a difference between a noise to be superimposed on the charge accumulator 41a and a noise to be superimposed on the charge accumulator 41b.

In the dummy pixel 10b, the line 57B, the plug 52B, the line 57A, the plug 52A, the line 53, and the contact plug 54 constitute at least part of the charge accumulator 41b illustrated in FIG. 1. In the configuration of the dummy pixel 10b illustrated as an example in FIG. 2A, the gate electrode 24g of the signal detection transistor 24, the line 57B, the plug 52B, the line 57A, the plug 52A, the line 53, the contact plug 54, the contact plug 55, and the impurity region 28d serving as one of the source region and the drain region of the reset transistor 28 function as charge accumulating regions that accumulate the electric charges generated during a resetting operation and the electric charges attributed to noises generated by an operation and the like of the imaging device 100 during an exposure period to be described later.

Meanwhile, in the dummy pixel 10b, the plug 52B is the plug located closest to the photoelectric conversion layer 15 among the plugs provided to the dummy pixel 10b and electrically connected to the contact plug 54. A distance from a surface 52Bs of the plug 52B located closest to the photoelectric conversion layer 15, which is an upper surface of the plug 52B, is smaller than a distance from the surface 52B s to the semiconductor substrate 20. The distance from the surface 52Bs to the photoelectric conversion layer 15 is equivalent to a length between the surface 52Bs to a lower surface 15s of the photoelectric conversion layer 15 opposed to the surface 52Bs. Meanwhile, the distance from the surface 52Bs the semiconductor substrate 20 is equivalent to a length between the surface 52Bs and an upper surface 20s of the semiconductor substrate 20. The plug 52B of the dummy pixel 10b is an example of a third plug and the surface 52Bs is an example of a first surface. By providing the dummy pixel 10b with the plug 52B located closer to the photoelectric conversion layer 15 than to the semiconductor substrate 20 as described above, a wiring structure of the effective pixel 10a becomes similar to that of the dummy pixel 10b. Thus, it is possible to reduce the difference between the noise to be superimposed on the charge accumulator 41a and the noise to be superimposed on the charge accumulator 41b.

FIG. 2B is a schematic sectional view illustrating sectional structures of an effective pixel 10a1 and a dummy pixel 10b1 according to a modified example of the present embodiment. The imaging device 100 may include the effective pixel 10a1 and the dummy pixel 10b1 instead of the effective pixel 10a and the dummy pixel 10b. As compared to the effective pixel 10a and the dummy pixel 10b illustrated in FIG. 2A, the effective pixel 10a1 and the dummy pixel 10b1 are different in that the effective pixel 10a1 and the dummy pixel 10b1 is provided with a pixel electrode 11a that is formed across the effective pixel 10a1 and the dummy pixel 10b1 instead of the respective pixel electrodes 11 of the effective pixel 10a and the dummy pixel 10b. Accordingly, a photoelectric converter 13a including the pixel electrode 11a, the counter electrode 12, and the photoelectric conversion layer 15 is formed across the effective pixel 10a1 and the dummy pixel 10b1. In the present modified example, the pixel electrode 11a is an example of the first pixel electrode. In the effective pixel 10al, the contact plug 54 is electrically connected to the photoelectric conversion layer 15 through the pixel electrode 11a. Meanwhile, in the dummy pixel 10b1, the contact plug 54 and the gate electrode 24g are electrically insulated from the pixel electrode 11a. The respective gate electrodes 24g of the effective pixel 10a1 and the dummy pixel 10b1 overlap the pixel electrode 11a in plan view.

According to this configuration, the effective pixel 10a1 can use the signal charges generated in the photoelectric conversion layer 15 in the photoelectric converter 13a of the dummy pixel 10b1. Thus, it is possible to improve sensitivity of the effective pixel 10al.

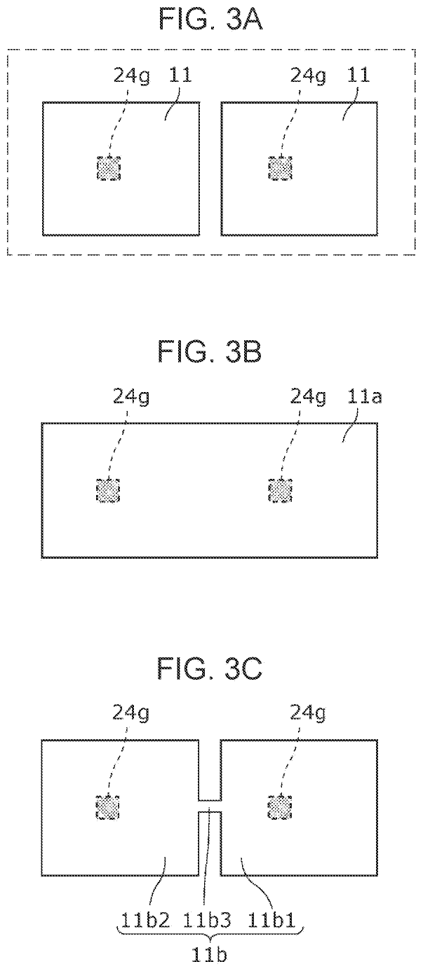

FIGS. 3A to 3C are plan views each illustrating a positional relation between the pixel electrode and the gate electrode 24g in each of the effective pixel and the dummy pixel according to the present embodiment. In each of FIGS. 3A to 3C, the shape of each pixel electrode in plan view is indicated with a solid line and the shape of each gate electrodes 24g in plan view is illustrated with a dashed line.

FIG. 3A illustrates the pixel electrodes 11 and the gate electrodes 24g of the effective pixel 10a and the dummy pixel 10b illustrated in FIG. 2A. As illustrated in FIG. 3A, the respective pixel electrodes 11 of the effective pixel 10a and the dummy pixel 10b have the same shape in plan view, for example. Accordingly, a difference during a manufacturing process occurs less between the effective pixel 10a and the dummy pixel 10b, so that the degrees of noises to occur in the respective pixels can be equalized. The shape in plan view of each pixel electrode 11 is a rectangular shape, for example. However, the pixel electrode 11 may take on a shape other than the rectangular shape such as a circular shape and a polygonal shape other than the rectangular shape.

FIG. 3B illustrates the pixel electrodes 11a and the gate electrodes 24g of the effective pixel 10a1 and the dummy pixel 10b1 illustrated in FIG. 2B. As illustrated in FIG. 3B, the respective pixel electrodes 11a of the effective pixel 10a1 and the dummy pixel 10b1 may be connected to each other. Accordingly, it is possible to improve the sensitivity of the effective pixel 10a1 by effectively using the photoelectric conversion layer 15 in the photoelectric converter 13a of the dummy pixel 10b1 as mentioned above. The shape in plan view of each pixel electrode 11a is a rectangular shape, for example. However, the pixel electrode 11a may take on a shape other than the rectangular shape such as a circular shape and a polygonal shape other than the rectangular shape.

Meanwhile, as illustrated in FIG. 3C, the imaging device 100 may include a pixel electrode 11b which is provided with an effective electrode portion 11b1 and a dummy electrode portion 11b2 provided to the effective pixel and the dummy pixel, respectively, and with a pixel electrode connector portion 11b3 that connects the effective electrode portion 11b1 to the dummy electrode portion 11b2. The effective electrode portion 11b1 and the dummy electrode portion 11b2 have the same shape in plan view. The shape in plan view of the effective electrode portion 11b1 and of the dummy electrode portion 11b2 is a rectangular shape, for example. However, the effective electrode portion 11b1 and the dummy electrode portion 11b2 may take on a shape other than the rectangular shape such as a circular shape and a polygonal shape other than the rectangular shape. Meanwhile, in terms of a direction perpendicular to a direction to connect the effective electrode portion 11b1 to the dummy electrode portion 11b2 in plan view, a length of each of the effective electrode portion 11b1 and the dummy electrode portion 11b2 is larger than a length of the pixel electrode connector portion 11b3. This configuration makes it possible to obtain both of effects of the above-described configurations of the pixel electrode 11 and the pixel electrode 11a.

In FIGS. 3A and 3C, the shapes in plan view as well as the areas of the pixel electrodes 11 in the effective pixel 10a and the dummy pixel 10b, or those of the effective electrode portion 11b1 and the dummy electrode portion 11b2 do not have to be the same. The shapes in plan view or the areas thereof may be adjusted differently in order to equalize the degrees of noises to be generated in the respective pixels.

### Operation of Imaging Device

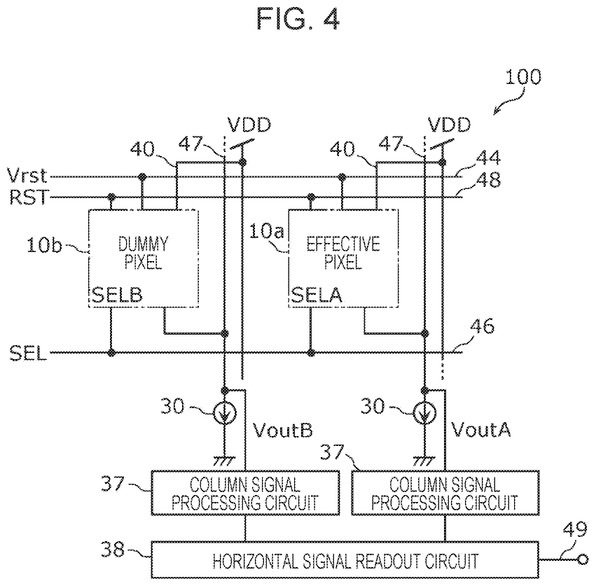

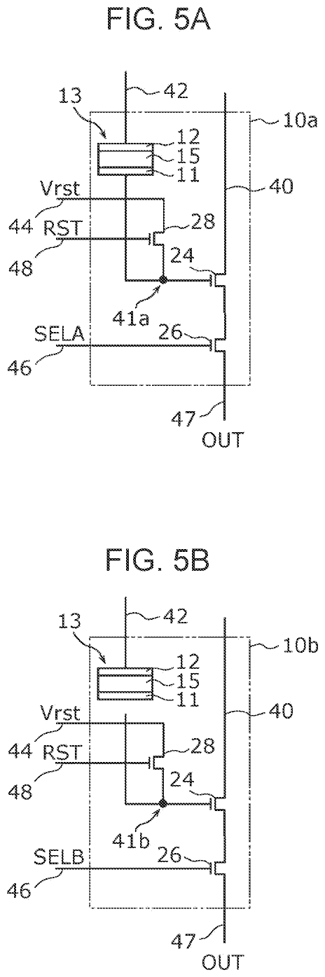

Next, a description will be given of an operation of the imaging device according to the present embodiment, namely, a method of driving the imaging device. FIG. 4 is a schematic circuit diagram of the imaging device 100. FIG. 5A is a circuit diagram of the effective pixel 10a in the imaging device 100. FIG. 5B is a circuit diagram of the dummy pixel 10b in the imaging device 100. The imaging device 100 illustrated in FIG. 4 is as same as the circuit configuration of the imaging device 100 illustrated in FIG. 1. FIG. 4 omits illustration of some of the constituents of the imaging device 100 such as the voltage supply circuit 32, the reset voltage source 34, the vertical scanning circuit 36, and the bias control line 42 of the imaging device 100 illustrated in FIG. 1. This omission also applies to other schematic circuit diagrams of imaging devices to be described later in other embodiments. Moreover, FIG. 4 omits illustration of the circuit configurations of the effective pixel 10a and the dummy pixel 10b, and details of the circuit configurations are illustrated in FIGS. 5A and 5B.

As illustrated in FIGS. 4 and 5A, the vertical signal line 47 connected to the output terminal of the address transistor 26 of the effective pixel 10a is connected to the constant-current source 30, thereby constituting a source follower together with the signal detection transistor 24 of the effective pixel 10a. An effective pixel output voltage VoutA that is a source follower output corresponding to the electric potential at the gate electrode 24g of the signal detection transistor 24 of the effective pixel 10a is outputted as the pixel signal to the column signal processing circuit 37 corresponding to the column of the effective pixels 10a.

As illustrated in FIGS. 4 and 5B, the vertical signal line 47 connected to the output terminal of the address transistor 26 of the dummy pixel 10b is connected to the constant-current source 30, thereby constituting a source follower together with the signal detection transistor 24 of the dummy pixel 10b. A dummy pixel output voltage VoutB that is a source follower output corresponding to the electric potential at the gate electrode 24g of the signal detection transistor 24 of the dummy pixel 10b is outputted as the pixel signal to the column signal processing circuit 37 corresponding to the column of the dummy pixels 10b. The effective pixel output voltage VoutA and the dummy pixel output voltage VoutB are simultaneously read out by the corresponding column signal processing circuits 37, respectively. Then, the column signal processing circuits 37 on adjacent rows are connected to each other with lines not illustrated in FIG. 4, for example, and one of the column signal processing circuit 37 generates a difference output signal Vdff (Vdff=VoutA−VoutB) between the effective pixel output voltage VoutA and the dummy pixel output voltage VoutB. The difference output signal Vdff is subjected to AD conversion by the column signal processing circuit 37 and is outputted to the horizontal signal readout circuit 38. The difference output signal Vdff is sequentially outputted form the horizontal signal readout circuit 38 to a not-illustrated signal processing circuit and the like at a later stage. Here, the column signal processing circuit 37 may output the AD-converted effective pixel output voltage VoutA and dummy pixel output voltage VoutB to the horizontal signal readout circuit 38 without generating the difference output signal Vdff, and the difference output signal Vdff may be generated by the signal processing circuit and the like at the later stage. Alternatively, the column signal processing circuit 37 may subject the effective pixel output voltage VoutA and the dummy pixel output voltage VoutB to the AD conversion and then generate the difference output signal Vdff from the effective pixel output voltage VoutA and the dummy pixel output voltage VoutB having been subjected to the AD conversion.

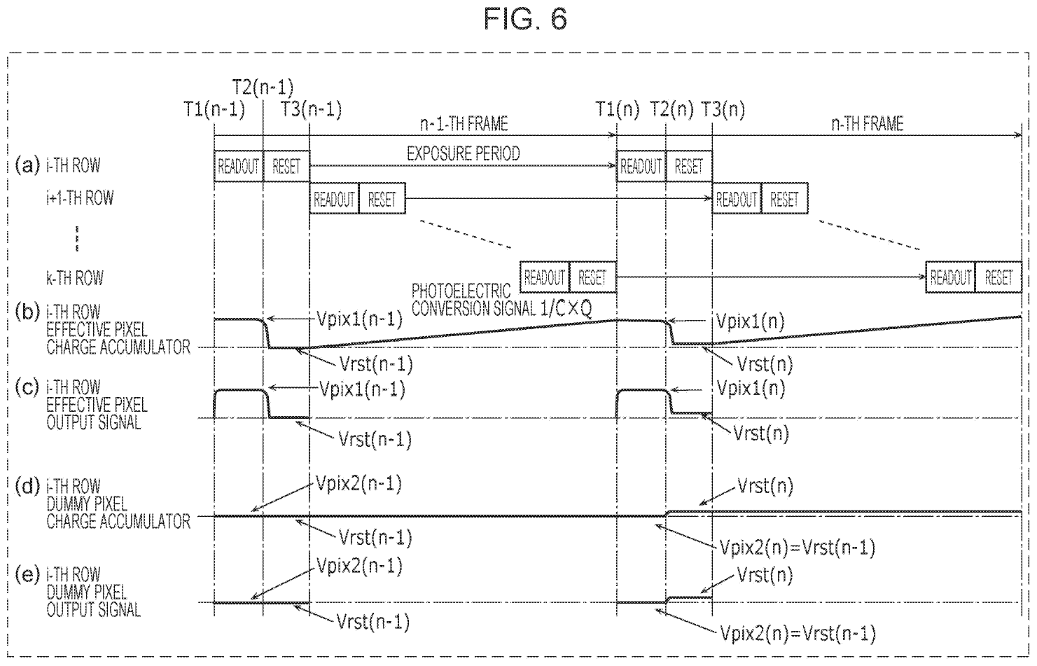

Next, a sequence of reading out signals by the imaging device 100 will be described. FIG. 6 is a diagram illustrating a sequence of a signal readout operation in frames by the imaging device 100. FIG. 6(a) schematically indicates operation timing of the pixels 10 on the respective rows in the pixel array PA. A graph in FIG. 6(b) depicts a change in electric potential at the charge accumulator 41a of the effective pixel 10a that belongs to an i-th row. A graph in FIG. 6(c) depicts a change in effective pixel output voltage VoutA of the effective pixel 10a that belong to the i-th row. A graph in FIG. 6(d) depicts a change in electric potential at the charge accumulator 41b of the dummy pixel 10b that belongs to the i-th row. A graph in FIG. 6(e) indicates a change in dummy pixel output voltage VoutB of the dummy pixel 10b that belong to the i-th row. In FIGS. 6(c) and 6(e), the output signals are expressed by using the expressions Vpix1, Vpix2, and the like which are the same as the electric potentials at the charge accumulator 41a and the charge accumulator 41b. Here, the expressions Vpix1, Vpix2 and the like in FIGS. 6(c) and 6(e) represent signals corresponding to the electric potentials Vpix1, Vpix2, and the like at the charge accumulator 41a and the charge accumulator 41b. In other words, the output signals are signals outputted after amplifying the electric potentials at the charge accumulator 41a and the charge accumulator 41b. The same applies to the drawings that illustrate more output signals to be described later.

The imaging device 100 performs readout of 60 frames per second in accordance with the readout sequence in FIG. 6, for example. An exposure period of each pixel 10 is assumed to be equal to 1/60 second.

The outputted signals from the effective pixel 10a and the dummy pixel 10b illustrated in FIGS. 6(c) and 6(e), respectively, are read out by the column signal processing circuit 37 at the timing of rectangles marked with “readout” illustrated in FIG. 6(a). Meanwhile, resetting operations are carried out for the effective pixel 10a and the dummy pixel 10b, respectively, at the timing of rectangles marked with “reset” illustrated in FIG. 6(a), whereby the electric potentials at the charge accumulator 41a and the charge accumulator 41b are reset to the reset voltage Vrst as illustrated in FIGS. 6(b) and 6(d). As described above, in the imaging device 100, each of the resetting operation and the readout operation is carried out at the same timing for the effective pixel 10a and the dummy pixel 10b on the same pixel row, for example.

A driving method for the imaging device of the laminated type according to the related art will be described to begin with. In the driving method for the imaging device of the laminated type according to the related art, the imaging device does not include the dummy pixels 10b and signals are read out of the effective pixels 10a only, for example. As illustrated in FIGS. 6(a) to 6(c), an exposure period from an n−1-th frame to an n-th frame of the pixel 10 that belongs to the i-th row is equivalent to a period from time T3(n−1) to time T1(n). An electric potential Vpix1(n) at the charge accumulator 41a at the time T1(n) is expressed as

Vpix1(n)=Vrst(n−1)+1/C×Q,

in which Vrst(n−1) denotes a reset voltage in a resetting operation of the effective pixel 10a to be started at time T2(n−1), C denotes a capacitance of the charge accumulator 41a, and Q denotes an amount of signal charges obtained by photoelectric conversion by the photoelectric converter 13 in accordance with an amount of incident light.

When the output signal is read out in an n-th frame, the effective pixel 10a reads a signal corresponding to Vpix1(n) from the time T1(n) to the time T2(n), and reads out a signal corresponding to Vrst(n) being the reset signal at the time T3(n) in the resetting operation of the effective pixel 10a in the n-th frame to be started at the time T2(n). Then, the column signal processing circuit 37 generates a signal corresponding to an electric potential Vsig1(n) calculated by

$$Vsig 1 ( n ) = Vpix 1 ( n ) - Vrst ( n ) = Vrst ( n - 1 ) + 1 / C \times Q - Vrst ( n )$$

as a photoelectric conversion signal generated by the incident light by obtaining a difference between the signal corresponding to Vpix1(n) and the signal corresponding to Vrst(n).

When Vrst(n−1)=Vrst(n) holds true in this instance, the signal corresponding to the electric potential Vsig1 calculated by

Vsig1=1/C×Q[V]

is obtained as the photoelectric conversion signal. However, in the case where Vrst(n−1) Vrst(n) holds true as illustrated in FIG. 6, the value Vsig1 turns out to be

Vsig1=1/C×Q+Vrst(n−1)−Vrst(n)[V],

and the accurate photoelectric conversion signal is therefore unavailable. Moreover, when the value Vrst(n−1)-Vrst(n) varies depending on the row of the effective pixel 10a to be read out and/or the frame to be read out due to noises that are superimposed on t the reset voltage Vrst, random or periodic signal differences emerge as noises in the outputs from the respective pixel rows even when the same amount of light is the same, whereby image quality is deteriorated. In other words, in the signal readout operation in the imaging device of the laminated type according to the related art, noises are prone to be generated as a consequence of using the reset voltage Vrst(n) in the resetting operation at the same frame as the frame from which the output signal is read out in order to obtain the photoelectric conversion signal.

In contrast, the imaging device 100 according to the present embodiment can effectively reduce the aforementioned noises by using the effective pixel 10a and the dummy pixel 10b, for example.

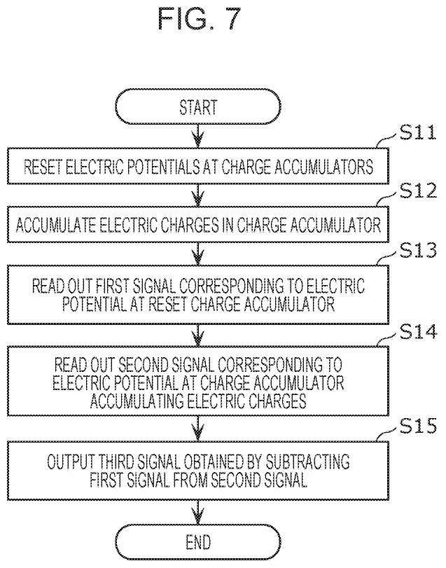

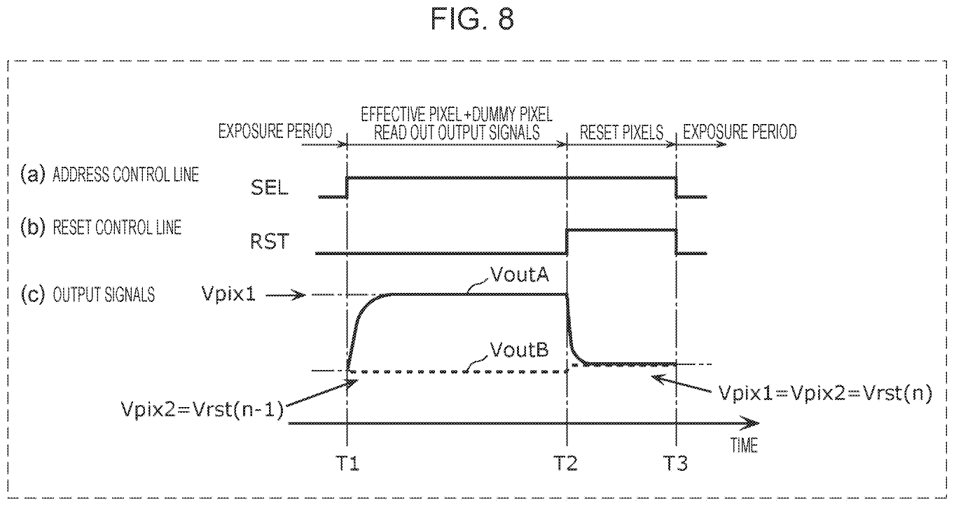

The method of driving the imaging device 100 according to the present embodiment will be described with reference to FIGS. 7 and 8 in addition to FIG. 6. First, a description will be given of a case where Vrst(n) and Vrst(n−1) failed to be fully removed in the above-described operation according to the related art deviate from each other. FIG. 7 is a flowchart illustrating an example of the method of driving the imaging device 100. In FIG. 7, step S11 is an example of a resetting step, step S12 is an example of an accumulating step, step S13 is an example of a first signal reading step, step S14 is an example of a second signal reading step, and step S15 is an example of an outputting step. FIG. 8 is a diagram illustrating a sequence of the signal readout operation in one frame by the imaging device 100. A graph in FIG. 8(a) indicates an electric potential at the address control line 46. In other words, this graph indicates timing of the scan signal SEL for selecting the effective pixel 10a and the dummy pixel 10b. Since the effective pixel 10a and the dummy pixel 10b are selected simultaneously, a scan signal SELA for selecting the effective pixel 10a and a scan signal SELB for selecting the dummy pixel 10b are the same scan signal SEL. A graph in FIG. 8(b) indicates an electric potential at the reset control line 48. In other words, this graph indicates timing of the reset signal RST for resetting the pixels 10. In FIG. 8(c), a graph plotted with a solid line indicates the effective pixel output voltage VoutA corresponding to the effective pixel 10a while a graph plotted with a dashed line indicates the dummy pixel output voltage VoutB corresponding to the dummy pixel 10b. FIG. 8 depicts the signal readout operation in the n-th frame in FIG. 6. Values of time T1, T2, and T3 in FIG. 8 correspond to the values of T1(n), T2(n), and T3(n) in FIG. 6, respectively. In the following description, the time without the suffix (n) such as the time T1, T2, or T3 will be explained as the time in the n-th frame.

First, in the effective pixel 10a and the dummy pixel 10b of the imaging device 100, the electric potentials at the charge accumulator 41a and the charge accumulator 41b are reset during a period from the time T2(n−1) to the time T3(n−1) illustrated in FIG. 6, respectively (step S11). The effective pixel 10a and the dummy pixel 10b reset the electric potentials at the charge accumulator 41a and the charge accumulator 41b, respectively, by using the same reset voltage source 34, for example. Thus, the electric potentials at the charge accumulator 41a and the charge accumulator 41b are reset to Vrst(n−1).

Next, in the exposure period, the effective pixel 10a accumulates the signal charges obtained by photoelectric conversion by the photoelectric conversion layer 15 after step S11 in the charge accumulator 41a that is reset in step S11 (step S12). In this instance, the electric potential at the charge accumulator 41a is equal to Vrst(n−1)+1/C×Q as mentioned earlier. Meanwhile, the dummy pixel 10b accumulates the electric charges, which originate from the noises generated in the 10b and the like after step S11, in the reset charge accumulator 41b. On the other hand, the dummy pixel 10b does not accumulate the signal charges obtained by photoelectric conversion by the photoelectric conversion layer 15 in the charge accumulator 41b. FIG. 6 illustrates the case where no noises are generated and no charges are therefore accumulated in the charge accumulator 41b. Accordingly, the electric potential at the charge accumulator 41b remains constant at Vrst(n−1) throughout the exposure period.

After step S12, the dummy pixel 10b reads out the dummy pixel output voltage VoutB corresponding to the electric potential at the charge accumulator 41b as the first signal corresponding to the electric potential at the reset charge accumulator 41a (step S13). The first signal is the signal corresponding to the electric potential at the charge accumulator 41a that is reset in the n−1-th frame. The charge accumulator 41a and the charge accumulator 41b are reset to the same electric potential Vrst(n−1), and the electric potential at the charge accumulator 41b remains constant at Vrst(n−1) throughout the exposure period. Accordingly, the dummy pixel output voltage VoutB in step S13 can be used as the first signal corresponding to the electric potential at the reset charge accumulator 41a. Meanwhile, concurrently with step S13, the effective pixel 10a reads out the effective pixel output voltage VoutA corresponding to the electric potential at the charge accumulator 41a, in which the electric charges are accumulated during the exposure period in step S12, as the second signal (step S14). The second signal is the signal corresponding to the electric potential at the charge accumulator 41a to be read out in the n-th frame. Note that the timing to carry out step S13 and step S14 is not limited to the aforementioned timing. For example, step S13 may be carried out during the accumulation of the signal charges in step S12. Meanwhile, one of the step S13 and step S14 may be carried out earlier instead of carrying out these steps concurrently.

To be more precise, in step S13 and step S14, the scan signal SEL reaches a high level in a period from the time T1 to the time T2 as illustrated in FIG. 8, and the address transistors 26 of the effective pixel 10a and the dummy pixel 10b are set to the on-state. As a consequence, the effective pixel output voltage VoutA corresponding to the electric potential at the charge accumulator 41a, namely,

Vpix1=Vrst(n−1)+1/C×Q

is outputted as the second signal to the vertical signal line 47 connected to the output terminal of the address transistor 26 of the effective pixel 10a. Meanwhile, the dummy pixel output voltage VoutB corresponding to the electric potential at the charge accumulator 41b, namely,

Vpix2=Vrst(n−1)

is outputted as the first signal to the vertical signal line 47 connected to the output terminal of the address transistor 26 of the dummy pixel 10b. These output signals are outputted to the column signal processing circuit 37, respectively. The column signal processing circuit 37 retains the first signal and the second signal thus outputted.

Next, the column signal processing circuit 37 outputs a third signal, which is obtained by subtracting the read first signal from the read second signal, to the horizontal signal readout circuit 38 (step S15). To be more precise, the column signal processing circuit 37 generates the third signal corresponding to the difference between the first signal and the second signal, namely,

Vsig1=Vpix1−Vpix2=Vrst(n−1)+1/C×Q−Vrst(n−1)=1/C×Q[V],

and outputs the generated third signal to the horizontal signal readout circuit 38. The third signal is used as the photoelectric conversion signal of the effective pixel 10a. In this driving method, the difference between the reset voltage Vrst(n−1) in the n−1-th frame being an immediately preceding frame to the n-th frame and the electric potential Vpix1 at the charge accumulator 41a in the n-th frame is used at the time of extracting the photoelectric conversion signal of the effective pixel 10a in the n-th frame unlike the driving method according to the related art. In this way, even when the reset voltage Vrst(n) after completion of the exposure period is deviated from the reset voltage Vrst(n−1) at the start of the exposure period, this deviation does not cause noises in the photoelectric conversion signal. Thus, it is possible to reduce the noises in the photoelectric conversion signal.

As illustrated in FIG. 8, after the readout of the output signals is completed, the effective pixel 10a and the dummy pixel 10b reset the electric potentials at the charge accumulator 41a and the charge accumulator 41b, respectively. To be more precise, the reset signal RST reaches a high level in a period from the time T2 to the time T3, and the reset transistors 28 of the effective pixel 10a and the dummy pixel 10b are set to the on-state. Accordingly, the respective electric potentials at the charge accumulator 41a and the charge accumulator 41b are reset to the reset voltage Vrst(n). After completion of the resetting operation, each of the scan signal SEL and the reset signal RST is set to a low level, and the address transistor 26 and the reset transistor 28 are set to an off-state. Then, the exposure period in the n-th frame is started. Here, the scan signal SEL may be set to the low level at the point of the time T2.

In the above-described method of driving the imaging device 100, the dummy pixel output voltage VoutB corresponding to the electric potential at the charge accumulator 41b is read out as the first signal corresponding to the electric potential at the reset charge accumulator 41a in step S13. However, the method is not limited only to this procedure. For example, in step S13, the effective pixel output voltage VoutA corresponding to the electric potential at the reset charge accumulator 41a may be read out as the first signal in the period between step S11 and step S12. The column signal processing circuit 37 may retain the first signal corresponding to the electric potential Vrst(n−1) at the charge accumulator 41a in the n−1-th frame during the exposure period, and may use the first signal thus retained in order to generate the third signal in step S15.

Next, a description will be given of a case where the signal noises not related to the signal charges generated in the photoelectric conversion layer 15 are superimposed on the charge accumulator 41a and the charge accumulator 41b due to a reason such as crosstalk originating from the peripheral lines during the exposure period.

In the effective pixel 10a, a capacitance value C1 of the charge accumulator 41a is composed of a parasitic capacitance Cp1 of the contact plug 54 and the peripheral lines thereof (such as the respective lines and the respective plugs illustrated in FIG. 1), a parasitic capacitance Cp2 of the reset transistor 28, and an input capacitance Cp3 of the signal detection transistor 24. In other words, the capacitance value C1 is expressed by:

C1=Cp1+Cp2+Cp3.

For example, the parasitic capacitance Cp2 includes a drain-gate overlap capacitance, a drain-substrate capacitance, a drain-source capacitance, and the like. The input capacitance Cp3 is a sum of the parasitic capacitances between the gate and the drain, the gate and the source, and the gate and the substrate, for example.

Likewise, in the dummy pixel 10b, a capacitance value C2 of the charge accumulator 41b is composed of a parasitic capacitance Cp1′ of the contact plug 54 and the peripheral lines thereof, a parasitic capacitance Cp2′ of the reset transistor 28, and an input capacitance Cp3′ of the signal detection transistor 24. In other words, the capacitance value C2 is expressed by:

C2=Cp1′+Cp2′+Cp3′.

As illustrated in FIGS. 1, 2A, and the like, the only difference between the effective pixel 10a and the dummy pixel 10b is the presence or absence of the plug 52C, and the circuits, the plugs, and the lines therein are constructed almost with the same structures and the same layouts. Accordingly, the parasitic capacitances to compose the charge accumulator 41a are substantially the same as the parasitic capacitances that compose the charge accumulator 41b.

It is known that a crosstalk noise originating from the peripheral lines and the peripheral circuits is propagated through the capacitance components and a level of such a noise is determined by a capacitance ratio between a source of generation of the noise and a counterpart that receives the noise. For instance, when the parasitic capacitance Cp1 between the contact plug 54 and the contact plug 55 in the effective pixel 10a is equal to the parasitic capacitance Cp1′ between the contact plug 54 and the contact plug 55 in the dummy pixel 10b, an amount of crosstalk noises to be propagated to the charge accumulator 41a of the effective pixel 10a from the contact plug 55 through the contact plug 54 therein is equal to an amount of crosstalk noises to be propagated to the charge accumulator 41b of the dummy pixel 10b from the contact plug 55 through the contact plug 54 therein. Likewise, when the effective pixel 10a and the dummy pixel 10b have the same circuits and the same layout, a capacitance value of the parasitic capacitances Cp2+Cp3 between the charge accumulator 41a and the respective transistors is equal to a capacitance value of the parasitic capacitances Cp2′+Cp3′ between the charge accumulator 41b and the respective transistors. As a consequence, the amounts of crosstalk noises to be propagated to the charge accumulator 41a and the charge accumulator 41b, respectively, through the pixel circuits including the transistors and the like are substantially equal to each other.

When the amount of crosstalk noises propagated from the peripheral lines and the peripheral circuits to the charge accumulator 41a in the exposure period from the resetting operation in the n−1-th frame to the readout in the n-th frame is defined as N1n while the amount of crosstalk noises propagated from the peripheral lines and the peripheral circuits to the charge accumulator 41b in this period is defined as N2n, the respective electric potentials Vpix1 and Vpix2 at the charge accumulator 41a and the charge accumulator 41b after the exposure period are expressed by

Vpix1=Vrst(n−1)+1/C1×Q+N1n, and

Vpix2=Vrst(n−1)+N2n.

The amounts of crosstalk noises to be propagated to the charge accumulator 41a and the charge accumulator 41b are substantially equal to each other and N1n=N2n holds true. Accordingly, the column signal processing circuit 37 generates the photoelectric conversion signal corresponding to

Vsig1=Vpix1−Vpix2=1/C1×Q

as the electric potential representing the difference therebetween. Thus, it is possible to eliminate the effect of the crosstalk noises.

In addition, as illustrated in FIGS. 6 and 8, the dummy pixel 10b and the effective pixel 10a read out the dummy pixel output voltage VoutB and the effective pixel output voltage VoutA simultaneously and the column signal processing circuit 37 or the like generates the photoelectric conversion signal corresponding to the difference therebetween. In this way, an effect of accurately removing a common mode noise to be superimposed on the pixels and the vertical signal line in a signal readout period is achieved as well.

As described above, since the imaging device 100 includes the dummy pixel 10b, the imaging device 100 can reduce effects not only of the noises attributed to the deviation between the reset voltage Vrst(n−1) at the start of the exposure period and the reset voltage Vrst(n) after completion of the exposure period, but also of the crosstalk noises to be generated during the exposure period.

### Embodiment 2

Next, an imaging device according to Embodiment 2 will be described. The following description of the Embodiment 2 will be mainly focused on different features from those in the Embodiment 1 while omitting or simplifying the explanations of the features in common.

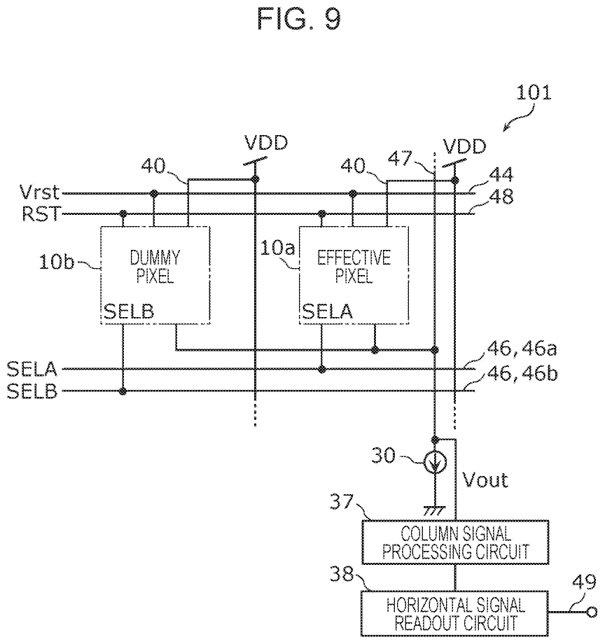

FIG. 9 is a schematic circuit diagram of an imaging device 101 according to the present embodiment. Circuit configurations of the effective pixel 10a and the dummy pixel 10b in the imaging device 101 are the same as those in the imaging device 100, which are as illustrated in FIGS. 5A and 5B.

As illustrated in FIG. 9, in comparison with the imaging device 100 according to the Embodiment 1, the imaging device 101 is different in that the effective pixel 10a and the dummy pixel 10b adjacent to each other read out both the output signal from the dummy pixel 10b and the output signal from the effective pixel 10a as the respective output signals Vout by using the single vertical signal line 47. In the imaging device 101, the signal outputted from the signal detection transistor 24 of the effective pixel 10a and the signal outputted from the signal detection transistor 24 of the dummy pixel 10b are inputted to the vertical signal line 47. In other words, the output terminal of the address transistor 26 of the effective pixel 10a and the output terminal of the address transistor 26 of the dummy pixel 10b are connected to the common vertical signal line 47. The vertical signal line 47 is an example of a first signal line. Meanwhile, in comparison with the imaging device 100, the imaging device 101 is different in that the imaging device 101 is provided with two address control lines 46 including an address control line 46a and an address control line 46b which correspond to the same pixel row. For this reason, a scan signal SELA is applied to the control terminal of the address transistor 26 of the effective pixel 10a through the address control line 46a, and a scan signal SELB is applied to the control terminal of the address transistor 26 of the dummy pixel 10b through the address control line 46b. Thus, the reading operations of the output signals from the effective pixel 10a and the dummy pixel 10b are controlled independently of each other. This makes it possible to reduce the number of the vertical signal lines 47 and thus to reduce the wiring area in the imaging device 101.

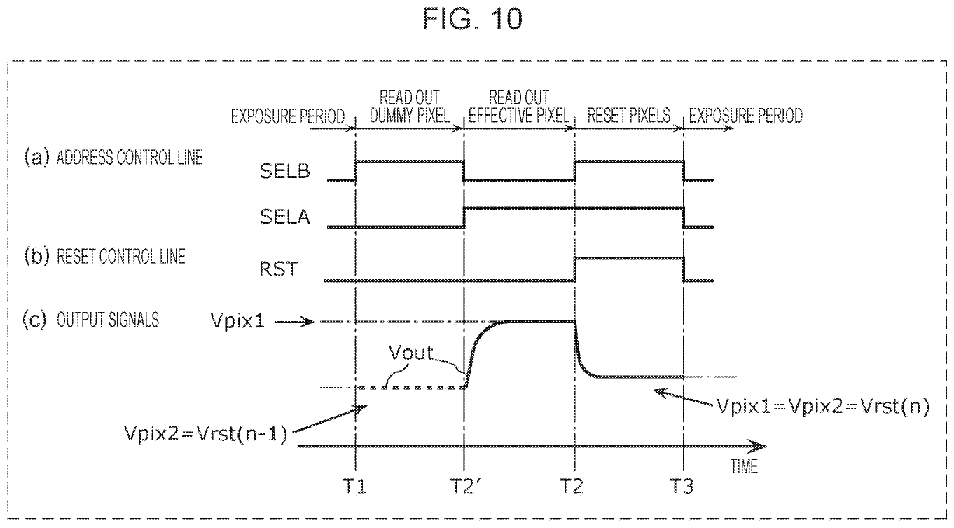

Next, a sequence of reading out signals by the imaging device 101 will be described. FIG. 10 is a diagram illustrating a sequence of a signal readout operation of the imaging device 101. Graphs depicted in FIGS. 10(a) to 10(c) are graphs on the same items as those in the graphs depicted in FIGS. 8(a) to 8(c). The graph in FIG. 10(b) is the same as the graph in FIG. 8(b). In FIG. 10(a), “SELA” denotes the electric potential at the address control line 46a while “SELB” denotes the electric potential at the address control line 46b. In FIG. 10(c), the output signal corresponding to the effective pixel 10a in the output signal Vout is indicated with a solid line while the output signal corresponding to the dummy pixel 10b therein is indicated with a dashed line.

As illustrated in FIG. 10, the scan signal SELB is set to a high level in a period from time T1 to time T2′, and the output signal Vout corresponding to the electric potential at the charge accumulator 41b, namely,

Vpix2=Vrst(n−1)

is outputted as the first signal to the vertical signal line 47 connected to the output terminal of the address transistor 26 of the dummy pixel 10b. This output signal Vout is retained by the column signal processing circuit 37.

Subsequently, the scan signal SELB is set to a low level at the time T2′ and the address transistor 26 of the dummy pixel 10b is set to the off-state. Then, the scan signal SELA is set to a high level in a period from the time T2′ to time T2, and the output signal Vout corresponding to the electric potential at the charge accumulator 41a, namely,

Vpix1=Vrst(n−1)+1/C×Q

is outputted as the second signal to the vertical signal line 47 connected to the output terminal of the address transistor 26 of the effective pixel 10a. This output signal Vout is retained by the column signal processing circuit 37. Meanwhile, the column signal processing circuit 37 performs AD conversion of either the third signal or the set of the first signal and the second signal used for generating the third signal.

Next, the column signal processing circuit 37 generates the third signal corresponding to the difference between the Vpix1 and the Vpix2, namely,

Vsig1=Vpix1−Vpix2=Vrst(n−1)+1/C×Q−Vrst(n−1)=1/C×Q[V],

and outputs the generated third signal as the photoelectric conversion signal to the horizontal signal readout circuit 38. Thus, the imaging device 101 can reduce the noises attributed to the deviation in the reset voltage and to the crosstalk noises during the exposure period as with the imaging device 100. Here, the period to set the scan signal SELA to the high level and the period to set the scan signal SELB to the high level in the course of reading out the pixel signals may be interchanged.

As illustrated in FIG. 10, after the readout of the output signals is completed, the effective pixel 10a and the dummy pixel 10b perform the resetting operations as with the case in FIG. 8. In the example of FIG. 10, the scan signal SELB is set to the high level again at the time T2. Here, the scan signal SELA and the scan signal SELB may be set to the low level during the period of resetting operations.

### Embodiment 3

Next, an imaging device according to Embodiment 3 will be described. The following description of the Embodiment 3 will be mainly focused on different features from those in the Embodiments 1 and 2 while omitting or simplifying the explanations of the features in common.

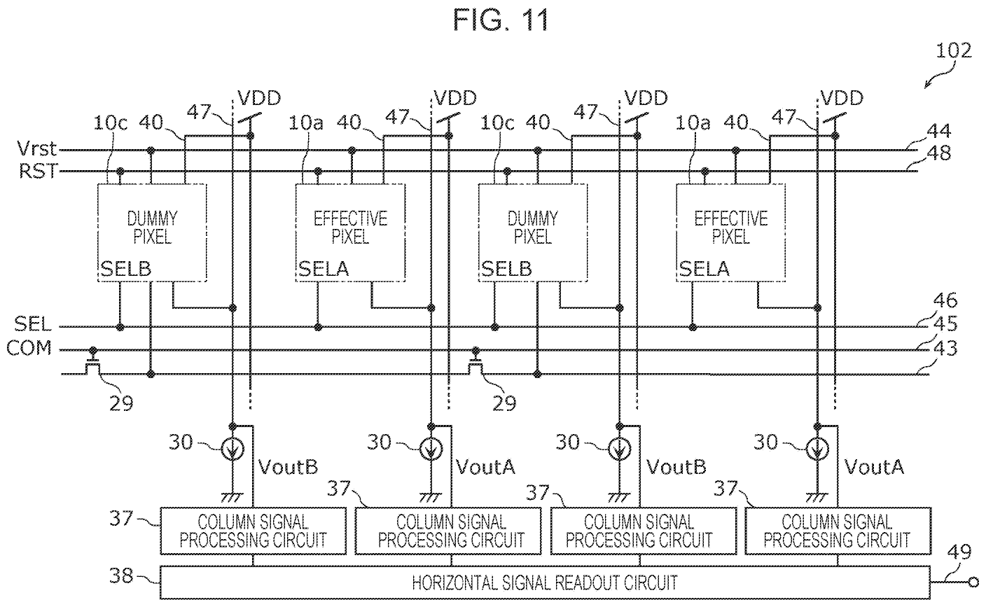

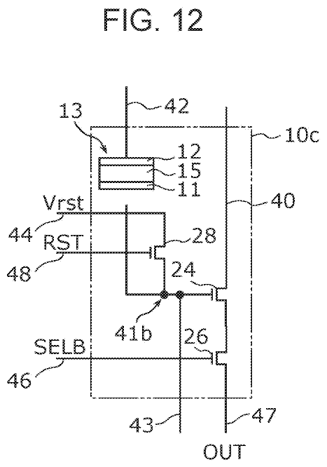

FIG. 11 is a schematic circuit diagram of an imaging device 102 according to the present embodiment. A circuit configuration of the effective pixel 10a in the imaging device 102 in FIG. 11 is illustrated in FIG. 5A and a circuit configuration of a dummy pixel 10c is illustrated in FIG. 12. FIG. 12 is a circuit diagram of the dummy pixel 10c in the imaging device 102.

As illustrated in FIGS. 11 and 12, in comparison with the imaging device 100 according to the Embodiment 1, the imaging device 102 is different in that the imaging device 102 includes the dummy pixel 10c instead of the dummy pixel 10b. Meanwhile, in comparison with the imaging device 100, the imaging device 102 is different in that the imaging device 102 further includes a voltage average line 43 to connect the charge accumulators 41b of the dummy pixels 10c that belong to the same pixel row, a voltage average switch 29 that controls connection to the voltage average line 43, and a average control line 45 that controls the voltage average switch 29. Accordingly, the charge accumulators 41b of the dummy pixels 10c are connected in common in the same row direction whereby the electric potentials at the charge accumulators 41b are averaged.

The dummy pixel 10c has the same configuration as that of the dummy pixel 10b except that the voltage average line 43 is connected to the charge accumulator 41b. In the imaging device 102, the charge accumulators 41b of at least two dummy pixels 10c on the same pixel row are electrically connected to each other through the voltage average line 43. In other words, at least part of the lines and the transistors provided to at least the two dummy pixels 10c on the same pixel row are electrically connected to one another through the voltage average line 43. For example, of the two dummy pixels 10c on the same pixel row illustrated in FIG. 11, the gate electrode 24g of the signal detection transistor 24 of one of the dummy pixels 10c is electrically connected to the gate electrode 24g of the signal detection transistor 24 of the other dummy pixel 10c. The signal detection transistor 24 in the one dummy pixel 10c is an example of the second transistor, the gate electrode 24g therein is an example of the second gate electrode, and the contact plug 54 therein is an example of the second plug. In the meantime, the signal detection transistor 24 in the other dummy pixel 10c is an example of a fourth transistor, the gate electrode 24g therein is an example of a fourth gate electrode, and the contact plug 54 therein is an example of a fifth plug. On the other hand, of the two effective pixels 10a illustrated in FIG. 11, the signal detection transistor 24 in one of the effective pixels 10a is an example of the first transistor, the gate electrode 24g therein is an example of the first gate electrode, and the contact plug 54 therein is an example of the first plug. In the meantime, the signal detection transistor 24 in the other effective pixel 10a is an example of a third transistor, the gate electrode 24g therein is an example of a third gate electrode, and the contact plug 54 therein is an example of a fourth plug.

The voltage average switch 29 is provided between the gate electrode 24g of the one dummy pixel 10c and the gate electrode 24g of the other dummy pixel 10c. An input terminal of the voltage average switch 29 is connected to the gate electrode 24g of the one dummy pixel 10c through the voltage average line 43 while an output terminal thereof is connected to the gate electrode 24g of the other dummy pixel 10c through the voltage average line 43. The voltage average switch 29 is an example of a first switch. The voltage average switch 29 is a field effect transistor, for example.

The average control line 45 is connected to a control terminal of the voltage average switch 29 and to the vertical scanning circuit 36 illustrated in FIG. 1 but not illustrated in FIG. 11. By controlling the electric potential at the average control line 45, it is possible to control on and off of the voltage average switch 29. As a consequence, it is possible to control whether or not to connect the charge accumulator 41b of the adjacent dummy pixel 10c.

Next, a sequence of the signal readout operation of the imaging device 102 will be described. The sequence of the signal readout operation of the imaging device 102 is the same as that by the imaging device 100 except the control by the average control line 45. Accordingly, explanations of the features in common will be omitted.

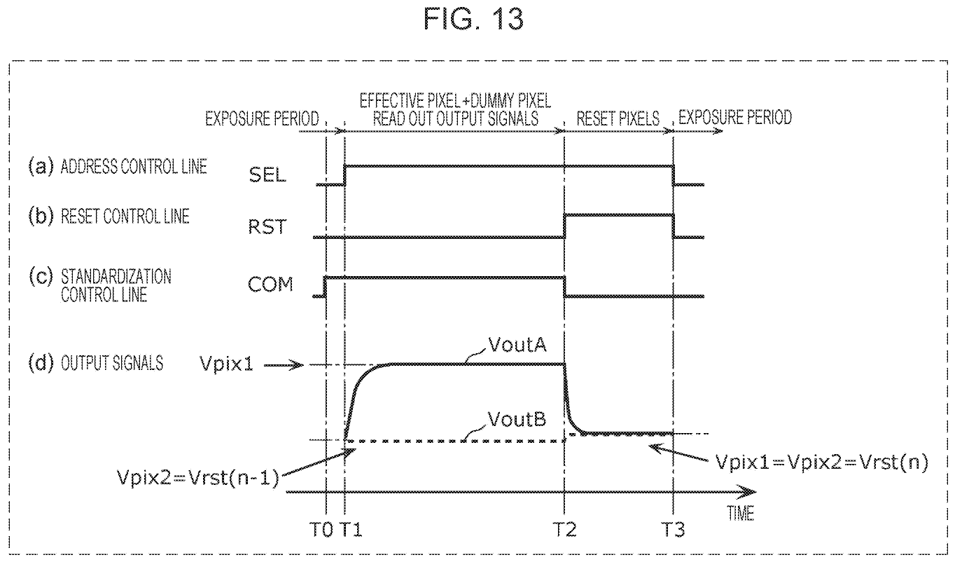

FIG. 13 is a diagram illustrating the sequence of the signal readout operation of the imaging device 102. Graphs in FIGS. 13(a), 13(b), and 13(d) are the same as the graphs in FIGS. 8(a), 8(b), and 8(c), respectively. A graph in FIG. 13(c) depicts an electric potential at the average control line 45. In other words, this graph depicts timing of a average signal COM to average the electric potential at the charge accumulator 41b of the adjacent dummy pixel 10c by using the voltage average line 43.

As illustrated in FIG. 13, the average signal COM is first set to a high level and the voltage average switch 29 is set to the on-state at time TO before starting the readout of the output signal. Thus, the charge accumulators 41b of the adjacent dummy pixels 10c in the horizontal direction of the pixel array PA, that is, of the dummy pixels 10c on the same pixel rows, are electrically connected to each other. Here, the timing to set the average signal COM to the high level may be any timing as long as that timing falls within a period from completion of the resetting operation of the previous frame to time T1.

Next, the scan signal SEL is set to a high level in a period from the time T1 to time T2, and the effective pixel output voltage VoutA and the dummy pixel output voltage VoutB corresponding to the electric potentials at the charge accumulator 41a and the charge accumulator 41b are read out, respectively. Then, in a period from the time T2 to time T3, the reset signal RST is set to a high level and the respective electric potentials at the charge accumulator 41a and the charge accumulator 41b are reset. Meanwhile, the average signal COM is set to a low level at the time T2 to start the resetting operation.

Now, a description will be given of an effect of connecting the charge accumulator 41b to each other. As described above, the noise signal as well as the signal corresponding to the reset voltage Vrst(n−1) in the immediately preceding frame are superimposed on the signal read out of the charge accumulator 41b of the dummy pixel 10c. If the noise originating from this additional noise signal is the crosstalk noise originating from the peripheral circuit, this crosstalk noise is also superimposed on the charge accumulator 41a of the effective pixel 10a, so that this noise can be removed by obtaining the difference between the signals. However, it is known that a random noise is generated by switching between on and off of the reset transistor 28 to control whether or not to apply the reset voltage Vrst to the charge accumulator 41a and the charge accumulator 41b for each pixel 10. In addition, a random noise may also be generated during the exposure period due to an influence of a defect in a pixel and the like.

Accordingly, the electric potential at the charge accumulator 41a when reading out the output signal is expressed by

Vpix1=Vrst(n−1)+1/C×Q+Nc(n−1)+Nrk(n−1),

while the electric potential at the charge accumulator 41b when reading out the output signal is expressed by

Vpix2=Vrst(n−1)+Nc(n−1)+Nrk′(n−1).

Here, Nc is the crosstalk noise in the charge accumulator 41a and the charge accumulator 41b, Nrk is the random noise in the charge accumulator 41a on a k-th column of the pixel array PA, and Nrk′ is the random noise in the charge accumulator 41b on a k′-th column of the pixel array PA. When the random noises are not averaged, the photoelectric conversion signal corresponding to the difference is a signal expressed by

$$Vsig = Vpix 1 - Vpix 2 = 1 / C \times Q + 1 / \sqrt{2} \times \sqrt{{\{ Nrk ( n - 1 ) \}}^{2} + {\{ {Nrk}^{′} ( n - 1 ) \}}^{2}} . \qquad Mathematical 1$$

As it is understood from this formula, this is the difference between the random noises in two pixels. Accordingly, the random noises can only be reduced by 1/√2.

On the other hand, when the random noises are averaged by connecting the charge accumulators 41b of the adjacent dummy pixel 10c to each other by using the voltage average line 43, a sum Nr′ of the random noises is expressed by the following formula:

$${Nr}^{′} = \sqrt{\frac{1}{N} {\sum }_{k = 0}^{N} {\{ {Nrk}^{′} ( n - 1 ) \}}^{2}} . \qquad Mathematical 2$$

Here, N is the number of columns of the dummy pixel 10c of which the charge accumulators 41b are connected to one another. For example, when the number of columns is equal to 4000 columns, the random noises in the charge accumulators 41b can be reduced to 1/4000^{1/2}≈ 1/63 according to the above-mentioned formula. Thus, the imaging device 102 can reduce the effect of the random noises at the time of the resetting operations. Moreover, when the charge accumulators 41b of the dummy pixels 10c are connected to each other before starting the readout of the output signal as in the above-described example, it is possible to reduce the random noises superimposed on the charge accumulators 41b during the exposure period.

Regarding the charge accumulators 41b of the dummy pixel 10c in the imaging device 102, all of the charge accumulators 41b of the dummy pixels 10c on the same pixel row may be connected to one another, or the charge accumulators 41b of the dummy pixels 10c corresponding to each color such as Gr, Gb, R, and B may be connected to one another.

Here, the timing to set the average signal COM to the high level may be the timing from the time T3 to an early phase in the exposure period. In this way, the noises such as the crosstalk noises may be superimposed on each dummy pixel 10c in an amount nearly equal to the noises on the effective pixel 10a adjacent the relevant dummy pixel 10c.

### Embodiment 4

Next, an imaging device according to Embodiment 4 will be described. The following description of the Embodiment 4 will be mainly focused on different features from those in the Embodiments 1 to 3 while omitting or simplifying the explanations of the features in common.

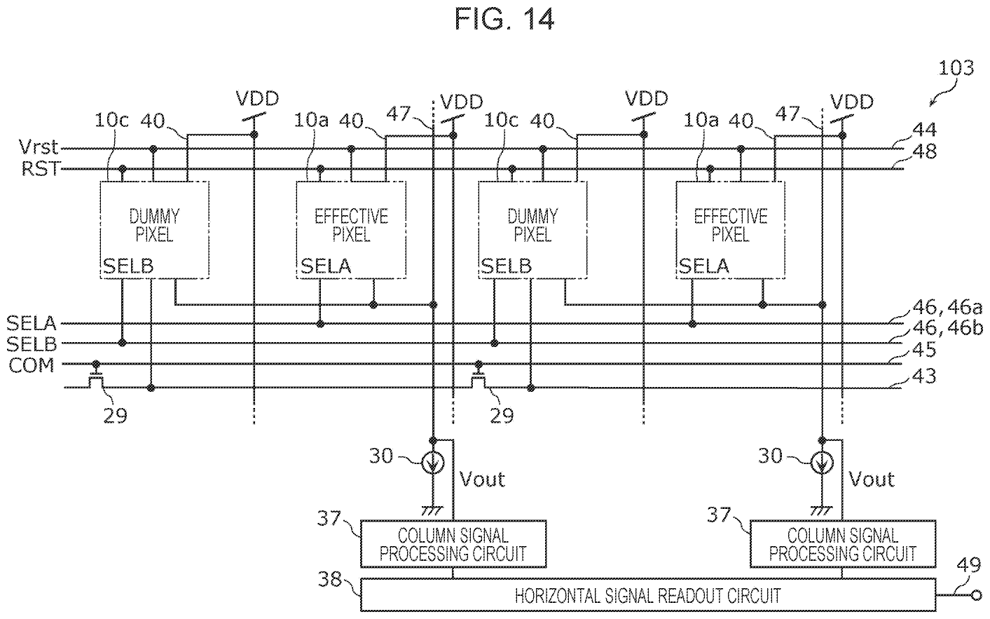

FIG. 14 is a schematic circuit diagram of an imaging device 103 according to the present embodiment. Circuit configurations of the effective pixel 10a and the dummy pixel 10c in the imaging device 103 are the same as those in the imaging device 102. The circuit configuration of the effective pixel 10a is illustrated in FIG. 5A and the circuit configuration of the dummy pixel 10c is illustrated in FIG. 12.

As illustrated in FIG. 14, in comparison with the imaging device 101 according to the Embodiment 2, the imaging device 103 is different in that the imaging device 103 includes the dummy pixel 10c similar to that in the imaging device 102 according to the Embodiment 3 instead of the dummy pixel 10b. Meanwhile, in comparison with the imaging device 101, the imaging device 103 is different in that the imaging device 103 further includes the voltage average line 43 to connect the charge accumulators 41b of the dummy pixels 10c that belong to the same pixel row, the voltage average switch 29 that controls connection to the voltage average line 43, and the average control line 45 that controls the voltage average switch 29.

Moreover, in comparison with the imaging device 102 according to the Embodiment 3, the imaging device 103 is different in that the imaging device 103 reads the output signal from the dummy pixel 10c and the output signal from the effective pixel 10a, the effective pixel 10a and the dummy pixel 10c being adjacent to each other, as the respective output signals Vout by using the single vertical signal line 47 as with the imaging device 101 according to the Embodiment 2. In the imaging device 103, the signal outputted from the signal detection transistor 24 of the effective pixel 10a and the signal outputted from the signal detection transistor 24 of the dummy pixel 10c are inputted to the vertical signal line 47. In other words, the output terminal of the address transistor 26 of the effective pixel 10a and the output terminal of the address transistor 26 of the dummy pixel 10c are connected to the common vertical signal line 47. Moreover, in comparison with the imaging device 102, the imaging device 103 is also different in that the imaging device 103 is provided with the two address control lines 46 including the address control line 46a and the address control line 46b corresponding to the same pixel row. Accordingly, the scan signal SELA is applied to the control terminal of the address transistor 26 of the effective pixel 10a through the address control line 46a, and the scan signal SELB is applied to the control terminal of the address transistor 26 of the dummy pixel 10c through the address control line 46b. Thus, the reading operations of the output signals from the effective pixel 10a and the dummy pixel 10c are controlled independently of each other.

As described above, the imaging device 103 has the configuration which is equivalent to a combination of the configuration of the imaging device 101 according to the Embodiment 2 and the configuration of the imaging device 102 according to the Embodiment 3.

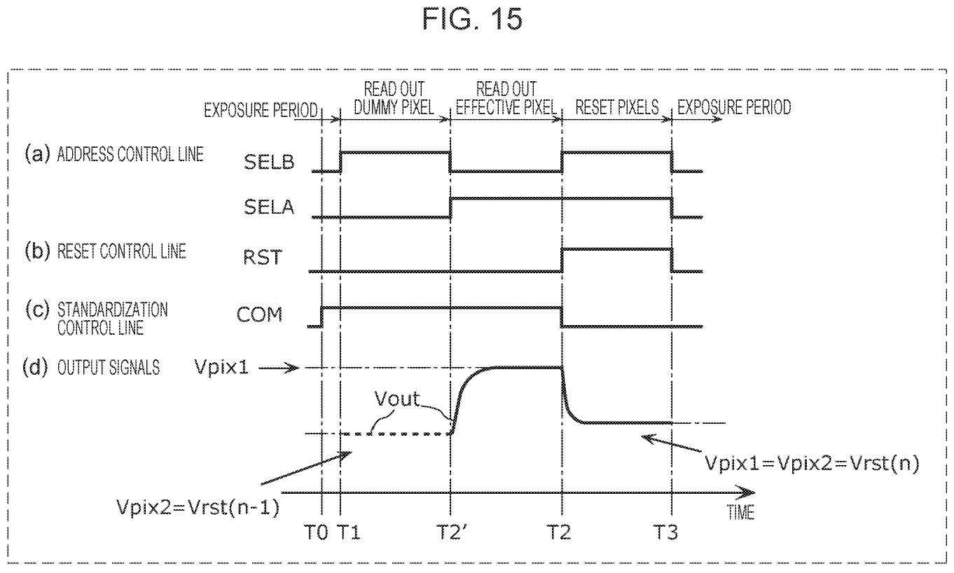

FIG. 15 is a diagram illustrating the sequence of the signal readout operation of the imaging device 103. Graphs in FIGS. 15(a), 15(b), and 15(d) are the same as the graphs in FIGS. 10(a), 10(b), and 10(c), respectively. Meanwhile, a graph in FIG. 15(c) is the same as the graph in FIG. 13(c). For this reason, the sequence of the signal readout operation of the imaging device 103 is the same as the descriptions with reference to FIGS. 10 and 13, and explanations will therefore be omitted.

According to the configurations and the signal readout operation as described above, the imaging device 103 can achieve effects of noise reduction and the like, which are equivalent to a combination of the effects described in the Embodiments 1, 2, and 3.

### Embodiment 5

Next, an imaging device according to Embodiment 5 will be described. The following description of the Embodiment 5 will be mainly focused on different features from those in the Embodiment 1 while omitting or simplifying the explanations of the features in common. The imaging device according to the Embodiment 5 has a pixel circuit configuration adopting an in-pixel feedback method.

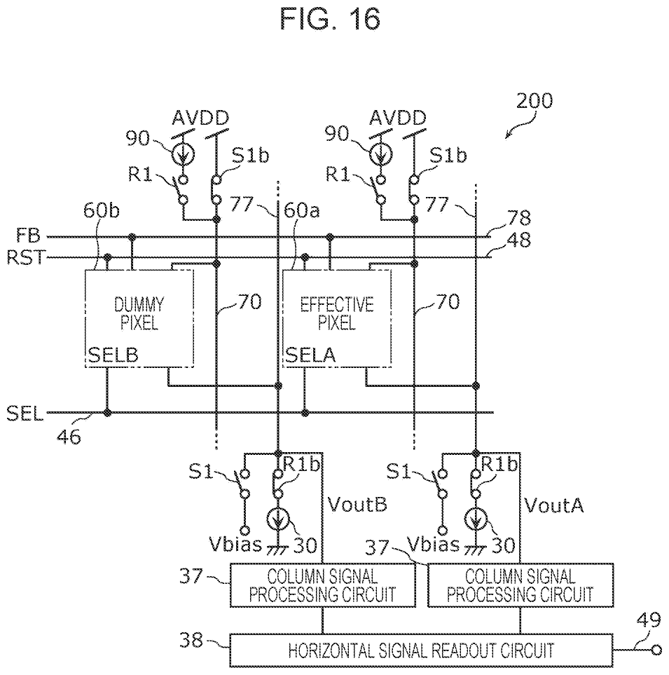

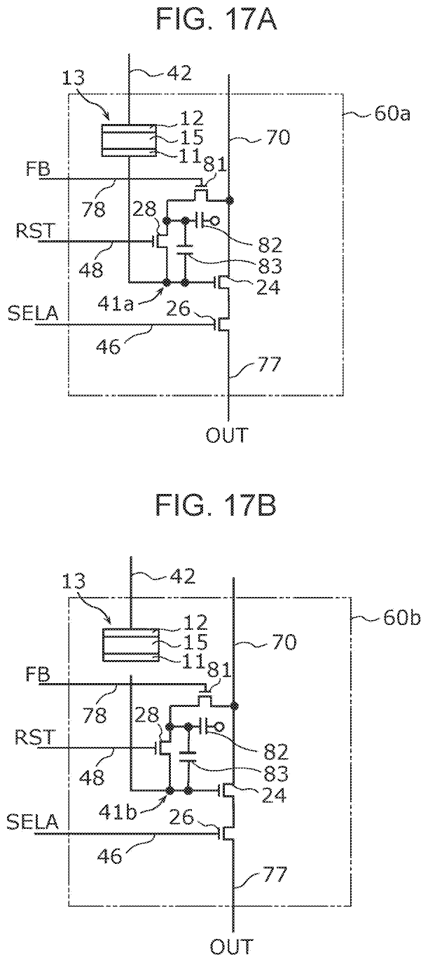

FIG. 16 is a schematic circuit diagram of an imaging device 200 according to the present embodiment. FIG. 17A is a circuit diagram of an effective pixel 60a in the imaging device 200. FIG. 17B is a circuit diagram of a dummy pixel 60b in the imaging device 200. A circuit configuration of the effective pixel 60a in FIG. 16 is illustrated in FIG. 17A, and a circuit configuration of the dummy pixel 60b therein is illustrated in FIG. 17B.

As illustrated in FIG. 16, in comparison with the imaging device 100 according to the Embodiment 1, the imaging device 200 is different in that the imaging device 200 is provided with the effective pixel 60a and the dummy pixel 60b instead of the effective pixel 10a and the dummy pixel 10b, and also includes peripheral circuits associated with the effective pixel 60a and the dummy pixel 60b. Moreover, as illustrated in FIG. 17A, in comparison with the effective pixel 10a according to the Embodiment 1, the effective pixel 60a is different in that the effective pixel 60a further includes the bandwidth control transistor 81, a capacitive element 82, a capacitive element 83, and a feedback control line 78 that controls the bandwidth control transistor 81. Furthermore, in comparison with the effective pixel 10a according to the Embodiment 1, the effective pixel 60a is also different in that the effective pixel 60a includes a power supply line 70 and a vertical signal line 77 instead of the power supply line 40 and the vertical signal line 47. Meanwhile, as with the difference in configuration between the effective pixel 10a and the dummy pixel 10b according to the Embodiment 1, for example, the only difference in configuration between the effective pixel 60a and the dummy pixel 60b lies in that plug 52C is not included in the interlayer insulating layer 50C illustrated in FIG. 1. In other words, in the effective pixel 60a, the contact plug 54 and the gate electrode 24g being the control terminal of the signal detection transistor 24 are electrically connected to the photoelectric conversion layer 15 and the pixel electrode 11. On the other hand, in the dummy pixel 60b, the contact plug 54 and the gate electrode 24g being the control terminal of the signal detection transistor 24 are electrically insulated from the photoelectric conversion layer 15 and the pixel electrode 11. As a consequence, the charge accumulator 41a of the effective pixel 60a is connected to the photoelectric conversion layer 15 while the charge accumulator 41b of the dummy pixel 60b is not connected to the photoelectric conversion layer 15.

As illustrated in FIG. 17A, the bandwidth control transistor 81 is connected between the power supply line 70 and the reset transistor 28, thereby constituting an in-pixel feedback amplifier at the time of the resetting operation. An input terminal of the bandwidth control transistor 81 is connected to the power supply line 70. An output terminal of the bandwidth control transistor 81 is connected to the input terminal of the reset transistor 28, one end of the capacitive element 82, and one end of the capacitive element 83. The bandwidth control transistor 81 is a field effect transistor, for example. The feedback control line 78 is connected to a control terminal of the bandwidth control transistor 81, and to the vertical scanning circuit 36 illustrated in FIG. 1 but not illustrated in FIG. 16. A state of the bandwidth control transistor 81 is determined by an electric potential at the feedback control line 78.

Each of the capacitive element 82 and the capacitive element 83 functions as a negative feedback capacitor when the in-pixel feedback amplifier resets the electric potential at the charge accumulator 41a, thereby reducing a random noise in the course of resetting the electric potential at the charge accumulator 41a. A random noise generated in the course of turning the reset transistor 28 off is also referred to as a reset noise. The one end of the capacitive element 82 is connected to the one end of the capacitive element 83, the input terminal of the reset transistor 28, and the output terminal of the bandwidth control transistor 81. A reference voltage VR, for example, is applied to another end of the capacitive element 82. The one end of the capacitive element 83 is connected to the one end of the capacitive element 82, the input terminal of the reset transistor 28, and the output terminal of the bandwidth control transistor 81. Another end of the capacitive element 83 is connected to the control terminal of the signal detection transistor 24 and the output terminal of the reset transistor 28. Each of the capacitive element 82 and the capacitive element 83 is a metal-insulator-metal (MIM) capacitor or a metal-insulator-semiconductor (MIS) capacitor, for example.

As illustrated in FIGS. 16 and 17A, the input terminal of the signal detection transistor 24 of the effective pixel 60a is connected to the power supply line 70. The power supply line 70 is connected to a switch S1b and a switch R1. The switch S1b controls whether or not to connect the power supply line 70 to an analog power supply AVDD. The switch R1 controls whether or not to connect the power supply line 70 to a constant-current source 90 that flows out of the analog power supply AVDD. The output terminal of the signal detection transistor 24 is connected to the input terminal of the address transistor 26. The output terminal of the address transistor 26 is connected to the vertical signal line 77. The vertical signal line 77 is connected to a switch Rib, a switch S1, and the column signal processing circuit 37. The switch R1b controls whether or not to connect the vertical signal line 77 to the constant-current source 30 that is connected to an analog ground. The switch S1 controls whether or not to connect the vertical signal line 77 to a voltage Vbias. Each of the switch S1b, the switch R1, the switch Rib, and the switch S1 is a field effect transistor, for example.

As illustrated in FIGS. 16 and 17B, the input terminal of the signal detection transistor 24 of the dummy pixel 60b is connected to the power supply line 70. The power supply line 70 is connected to a switch S1b and a switch R1. The output terminal of the signal detection transistor 24 is connected to the input terminal of the address transistor 26. The output terminal of the address transistor 26 is connected to the vertical signal line 77. The vertical signal line 77 is connected to a switch R1b, a switch S1, and the column signal processing circuit 37. In other words, relations of connection of the power supply line 70 and the vertical signal line 77 in the effective pixel 60a are the same as those in the dummy pixel 60b. Accordingly, the explanations of the same constituents in the dummy pixel 60b as those in the effective pixel 60a will be omitted.

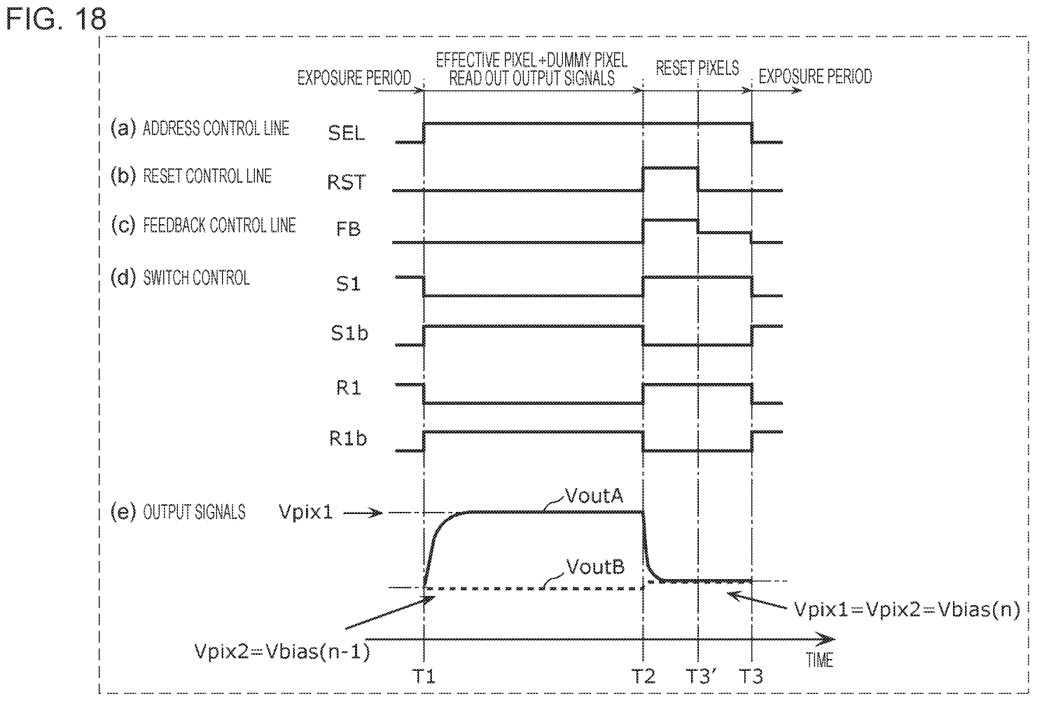

Next, a sequence of the signal readout operation of the imaging device 200 will be described. Note that explanations for the features in common with imaging device 100 will be omitted. FIG. 18 is a diagram illustrating the sequence of the signal readout operation of the imaging device 200. Graphs in FIGS. 18(a) and 18(b) are the same as the graphs in FIGS. 8(a) and 8(b). A graph in FIG. 18(c) depicts an electric potential at the feedback control line 78. In other words, this graph depicts timing of a bandwidth control signal FB to control a state of the bandwidth control transistor 81. A graph in FIG. 18(d) depicts timing to turn the switch S1b, the switch R1, the switch R1b, and the switch S1 on and off. A graph in FIG. 18(e) is the same as the graph in FIG. 8(c) except that the output signal corresponding to the electric potential at the time of the resetting operation is a signal corresponding to Vbias instead of the signal corresponding to Vrst.

As illustrated in FIG. 18, the effective pixel 60a and the dummy pixel 60b in a certain pixel row in the n-th frame are assumed to read out the signals corresponding to the electric potentials at the charge accumulator 41a and the charge accumulator 41b accumulated in the exposure period from the resetting operation in the n−1-th frame to the readout in the n-th frame. First, the scan signal SEL is set to a high level at time T1, thus turning the switch S1 off, turning the switch S1b on, turning the switch R1 off, and turning the switch R1b on. Accordingly, the effective pixel output voltage VoutA corresponding to the electric potential at the charge accumulator 41a of the effective pixel 60a and the dummy pixel output voltage VoutB corresponding to the electric potential at the charge accumulator 41b of the dummy pixel 60b are outputted, respectively, to the column signal processing circuit 37 through the vertical signal line 77. The column signal processing circuit 37 generates the photoelectric conversion signal in accordance with the same operation as the operation described in the Embodiment 1, and outputs the generated photoelectric conversion signal to the horizontal signal readout circuit 38.

Subsequently, at time T2, each of the reset signal RST and the bandwidth control signal FB is set to a high level, thus turning the switch S1 on, turning the switch S1b off, turning the switch R1 on, and turning the switch R1b off. Accordingly, the signal detection transistor 24 of each of the effective pixel 60a and the dummy pixel 60b, the vertical signal line 77, the power supply line 70, and the constant-current source 90 located ahead collectively form a source ground amplifier. The electric potentials at the charge accumulator 41a and the charge accumulator 41b are reset to Vbias in a period from the time T2 to time T3′, that is, in a period when the reset signal RST and the bandwidth control signal FB are each set to the high level.

Next, the bandwidth control signal FB is set to an intermediate voltage in a period from the time T3′ to time T3, whereby the bandwidth control transistor 81 functions as a resistor circuit and the negative feedback amplifier is thus formed. At the time T3, the bandwidth control signal FB is set to a low level, whereby the bandwidth control transistor 81 is set to an off-state and resetting of the electric potentials at the charge accumulator 41a and the charge accumulator 41b is completed. In the meantime, the switch S1 is turned off, the switch S1b is turned on, the switch R1 is turned off, and the switch R1b is turned on at the time T3.

By carrying out the resetting operation by using the configuration of the feedback amplifier as described above, it is possible to further reduce the reset noises attributed to the reset transistors 28 when resetting the charge accumulator 41a and the charge accumulator 41b.

In the imaging device 200 according to the present embodiment, the effective pixel output voltage VoutA corresponding to the electric potential Vpix1 and the dummy pixel output voltage VoutB corresponding to the electric potential Vpix2 are simultaneously obtained at the time T2, and the column signal processing circuit 37 at the later stage generates the photoelectric conversion signal that represents the difference therebetween. As described in the Embodiment 1 and the like, the electric potential at the charge accumulator 41b of the dummy pixel 60b is equivalent to “a reset electric potential at the point of start of the exposure period+the crosstalk noise during the exposure period”, while the electric potential at the charge accumulator 41a of the effective pixel 60a is equivalent to “the reset electric potential at the point of start of the exposure period+a photoelectric conversion electric potential corresponding to the amount of incident light+the crosstalk noise during the exposure period”. Accordingly, by obtaining the difference in output signal between the dummy pixel 60b and the effective pixel 60a, it is possible to obtain the photoelectric conversion signal while removing the noises at high accuracy therefrom.

### Embodiment 6

Next, an imaging device according to Embodiment 6 will be described. The following description of the Embodiment 6 will be mainly focused on different features from those in the Embodiments 1 to 5 while omitting or simplifying the explanations of the features in common.

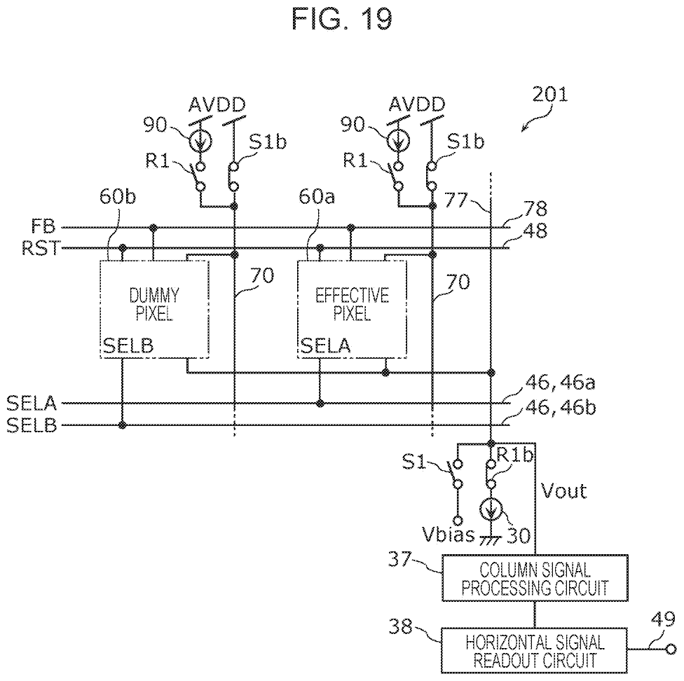

FIG. 19 is a schematic circuit diagram of an imaging device 201 according to the present embodiment. Circuit configurations of the effective pixel 60a and the dummy pixel 60b in the imaging device 201 are the same as those in the imaging device 200, which are illustrated in FIGS. 17A and 17B.

As illustrated in FIG. 19, in comparison with the imaging device 200 according to the Embodiment 5, the imaging device 201 is different in that the effective pixel 60a and the dummy pixel 60b adjacent to each other read out both the output signal from the dummy pixel 60b and the output signal from the effective pixel 60a as the respective output signals Vout by using the single vertical signal line 77 as with the imaging device 101 according to the Embodiment 2. In the imaging device 201, the signal outputted from the signal detection transistor 24 of the effective pixel 60a and the signal outputted from the signal detection transistor 24 of the dummy pixel 60b are inputted to the vertical signal line 77. In other words, the output terminal of the address transistor 26 of the effective pixel 60a and the output terminal of the address transistor 26 of the dummy pixel 60b are connected to the common vertical signal line 77. Meanwhile, in comparison with the imaging device 200, the imaging device 201 is also different in that the imaging device 201 is provided with the two address control lines 46 including the address control line 46a and the address control line 46b which correspond to the same pixel row. For this reason, the scan signal SELA is applied to the control terminal of the address transistor 26 of the effective pixel 60a through the address control line 46a, and the scan signal SELB is applied to the control terminal of the address transistor 26 of the dummy pixel 60b through the address control line 46b. Thus, the reading operations of the output signals from the effective pixel 60a and the dummy pixel 60b are controlled independently of each other. This makes it possible to reduce the number of the vertical signal lines 77 and thus to reduce the wiring area in the imaging device 201 and to reduce parasitic capacitances among the lines. As a consequence, the imaging device 201 can reduces the noises.

Moreover, in comparison with the imaging device 101 according to the Embodiment 2, the imaging device 201 is different in that the imaging device 201 is provided with the effective pixel 60a and the dummy pixel 60b instead of the effective pixel 10a and the dummy pixel 10b, and also includes peripheral circuits associated with the effective pixel 60a and the dummy pixel 60b. In other words, the difference between the imaging device 201 and the imaging device 101 is the same difference between the imaging device 100 according to the Embodiment 1 and the imaging device 200 according to the Embodiment 5.

As described above, the imaging device 201 has the configuration which is equivalent to a combination of the configuration of the imaging device 101 according to the Embodiment 2 and the configuration of the imaging device 200 according to the Embodiment 5.

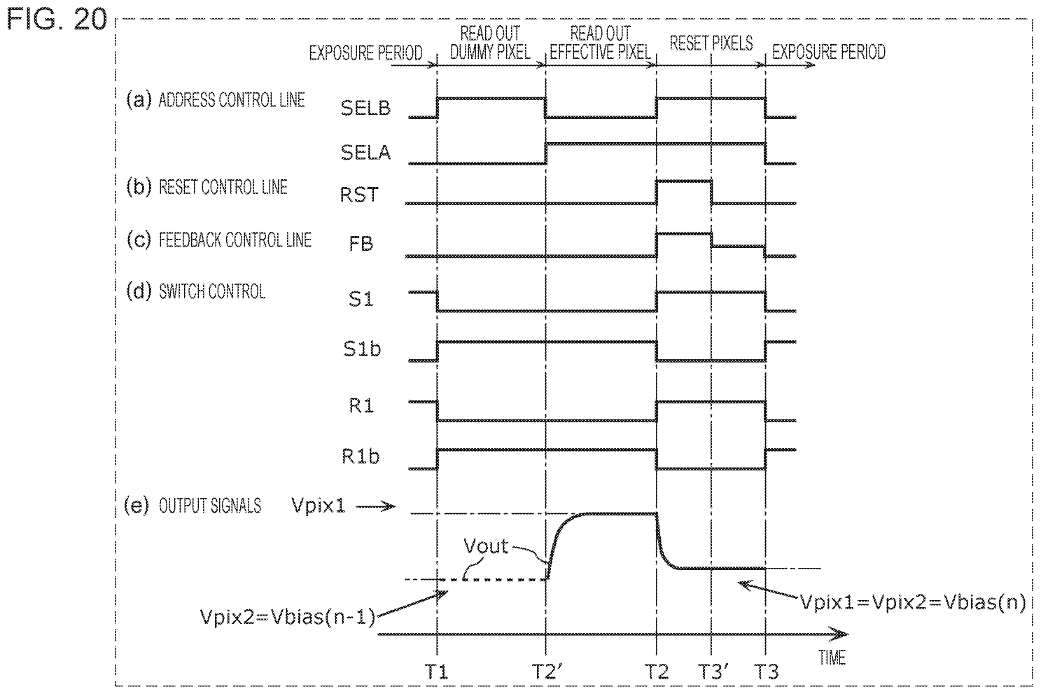

Next, a sequence of the signal readout operation of the imaging device 201 will be described. FIG. 20 is a diagram illustrating the sequence of the signal readout operation of the imaging device 201. A graph in FIG. 20(a) is the same as the graph in FIG. 10(a). Graphs in FIGS. 20(b) to 20(d) are the same as the graphs in FIGS. 18(b) to 18(d). A graph in FIG. 20(e) is the same as the graph in FIG. 10(e) except that the output signal corresponding to the electric potential at the time of the resetting operation is a signal corresponding to Vbias instead of the signal corresponding to Vrst.

As illustrated in FIG. 20, the effective pixel 60a and the dummy pixel 60b in a certain pixel row in the n-th frame are assumed to read out the signals corresponding to the electric potentials at the charge accumulator 41a and the charge accumulator 41b accumulated in the exposure period from the resetting operation in the n−1-th frame to the readout in the n-th frame. First, the scan signal SELB is set to a high level at time T1, thus turning the switch S1 off, turning the switch S1b on, turning the switch R1 off, and turning the switch R1b on. Accordingly, the output signal Vout corresponding to the electric potential at the charge accumulator 41b of the dummy pixel 60b is read out by the vertical signal line 77, and is retained at the column signal processing circuit 37.

Subsequently, at time T2′, the scan signal SELB is set to a low level whereby the output from the dummy pixel 60b is discontinued. Meanwhile, the scan signal SELA is set to a high level at the time T2′, whereby the output signal Vout corresponding to the electric potential at the charge accumulator 41a of the effective pixel 60a is read out by the vertical signal line 77, and is retained at the column signal processing circuit 37. The column signal processing circuit 37 generates the photoelectric conversion signal by using the difference between the output signal Vout corresponding to the electric potential at the charge accumulator 41a and the output signal Vout corresponding to the electric potential at the charge accumulator 41b, and outputs the generated photoelectric conversion signal to the horizontal signal readout circuit 38.

Next, at time T2, the scan signal SELB, the reset signal RST, and the bandwidth control signal FB are each set to a high level, thus turning the switch S1 on, turning the switch S1b off, turning the switch R1 on, and turning the switch R1b off. The same operation as that described with reference to FIG. 18 is carried out in a period from the time T2 to time T3. In this way, it is possible to further reduce the reset noises attributed to the reset transistors 28 when resetting the charge accumulator 41a and the charge accumulator 41b as with the imaging device 200 according to the Embodiment 5.

According to the configurations and the signal readout operation as described above, the imaging device 201 can achieve effects of noise reduction and the like, which are equivalent to a combination of the effects described in the Embodiments 1, 2, and 5.

### Embodiment 7

Next, an imaging device according to Embodiment 7 will be described. The following description of the Embodiment 7 will be mainly focused on different features from those in the Embodiments 1, 3, and 5 while omitting or simplifying the explanations of the features in common.

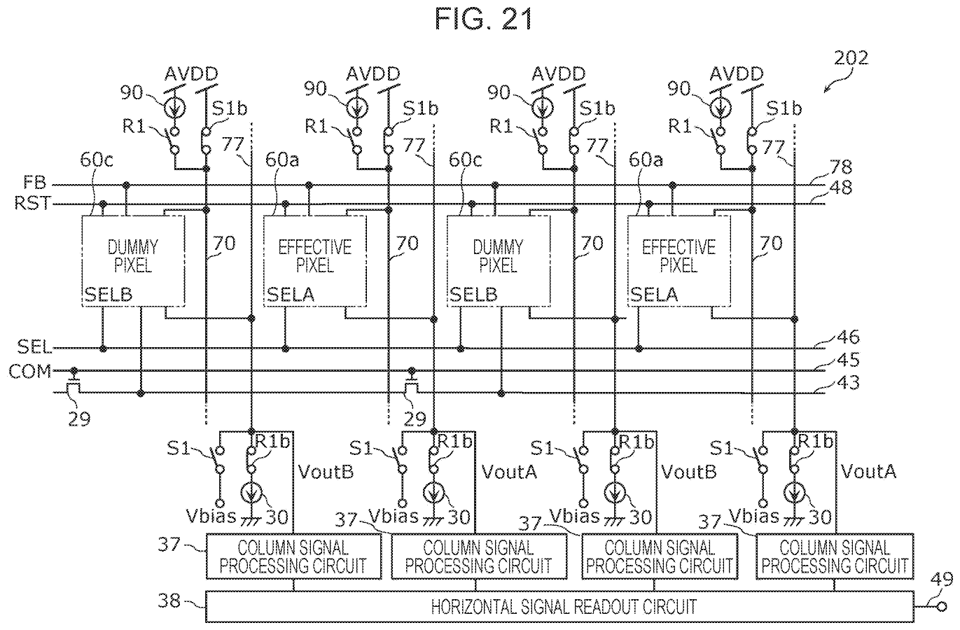

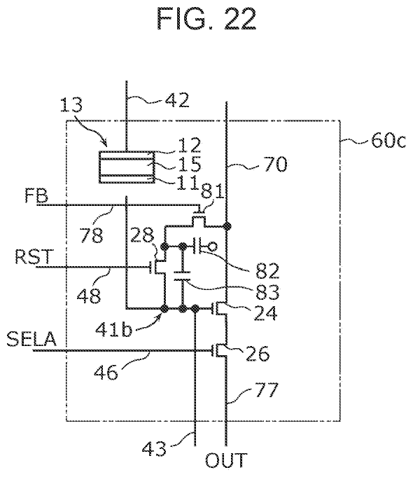

FIG. 21 is a schematic circuit diagram of an imaging device 202 according to the present embodiment. A circuit configuration of the effective pixel 60a of the imaging device 202 in FIG. 21 is illustrated in FIG. 17A, and a circuit configuration of a dummy pixel 60c thereof is illustrated in FIG. 22. FIG. 22 is a circuit diagram of the dummy pixel 60c in the imaging device 202.

As illustrated in FIGS. 21 and 22, in comparison with the imaging device 200 according to the Embodiment 5, the imaging device 202 is different in that the imaging device 202 includes the dummy pixel 60c instead of the dummy pixel 60b. Meanwhile, in comparison with the imaging device 200, the imaging device 202 is different in that the imaging device 202 further includes the voltage average line 43 to connect the charge accumulators 41b of the dummy pixels 60c that belong to the same pixel row, the voltage average switch 29 that controls connection to the voltage average line 43, and the average control line 45 that controls the voltage average switch 29 as with the imaging device 102 according to the Embodiment 3. Accordingly, the charge accumulators 41b of the dummy pixels 60c are connected in common in the same row direction whereby the electric potentials at the charge accumulators 41b are averaged as with the imaging device 102 according to the Embodiment 3.

The dummy pixel 60c has the same configuration as that of the dummy pixel 60b except that the voltage average line 43 is connected to the charge accumulator 41b. In the imaging device 202, the charge accumulators 41b of at least two dummy pixels 60c on the same pixel row are electrically connected to each other through the voltage average line 43. In other words, at least part of the lines and the transistors provided to at least the two dummy pixels 60c on the same pixel row are electrically connected to one another through the voltage average line 43.

As described above, the imaging device 202 has the configuration which is equivalent to a combination of the configuration of the imaging device 102 according to the Embodiment 3 and the configuration of the imaging device 200 according to the Embodiment 5.

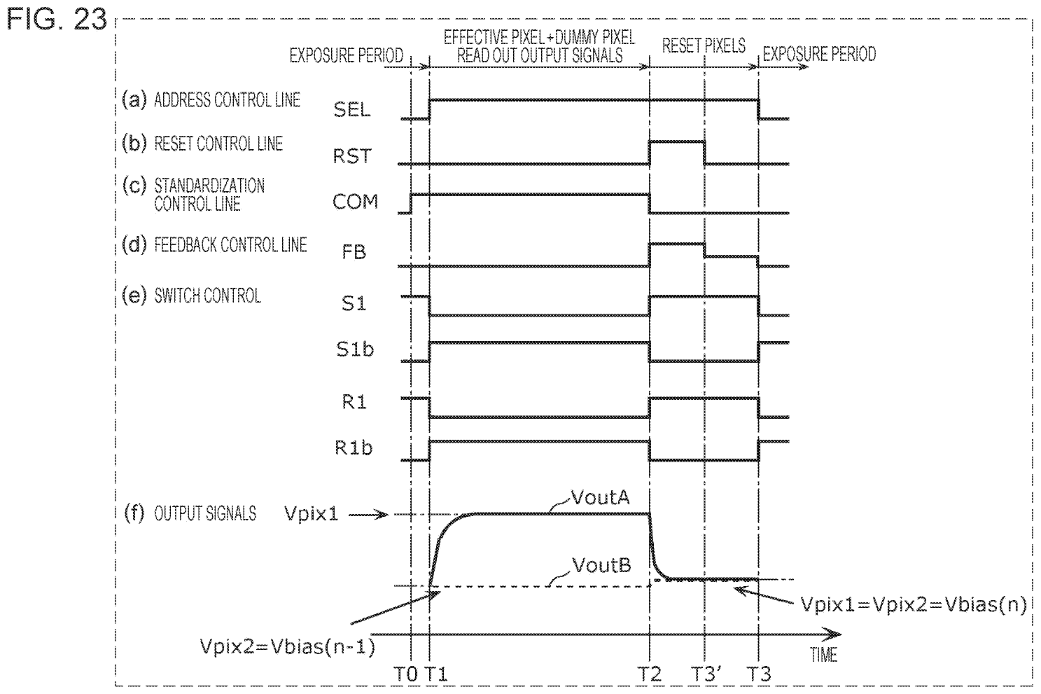

FIG. 23 is a diagram illustrating the sequence of the signal readout operation of the imaging device 202. Graphs in FIGS. 23(a), 23(b), 23(d), 23(e), and 23(f) are the same as the graphs in FIGS. 18(a), 18(b), 18(c), 18(d), and 18(e), respectively. Meanwhile, a graph in FIG. 23(c) is the same as the graph in FIG. 13(c). For this reason, the sequence of the signal readout operation of the imaging device 202 is the same as the descriptions with reference to FIGS. 18 and 13, and explanations will therefore be omitted.

According to the configurations and the signal readout operation as described above, the imaging device 202 can achieve effects of noise reduction and the like, which are equivalent to a combination of the effects described in the Embodiments 1, 3, and 5.

### Embodiment 8

Next, an imaging device according to Embodiment 8 will be described. The following description of the Embodiment 8 will be mainly focused on different features from those in the Embodiments 1 to 7 while omitting or simplifying the explanations of the features in common.

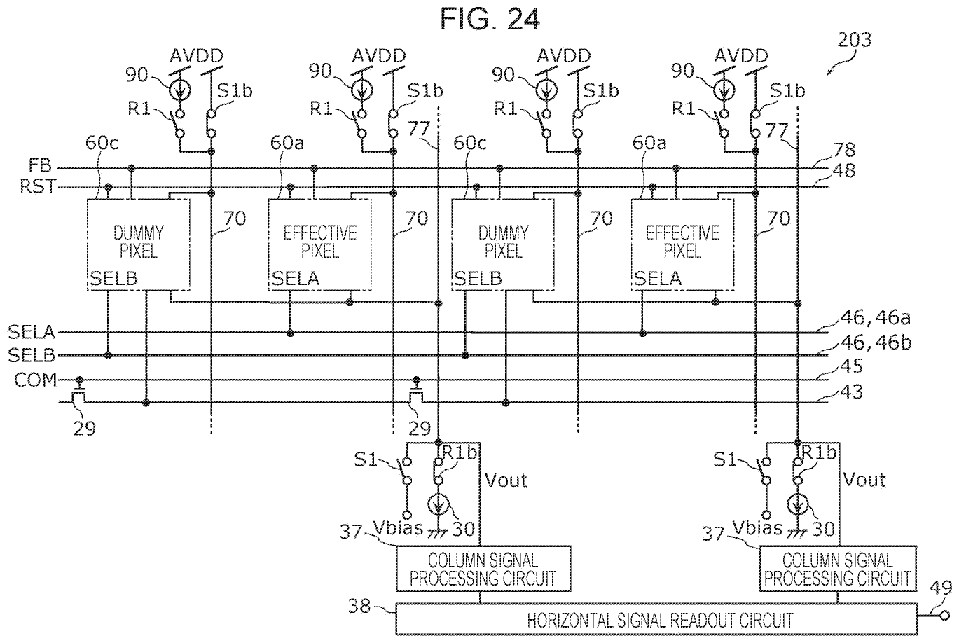

FIG. 24 is a schematic circuit diagram of an imaging device 203 according to the present embodiment. Circuit configurations of the effective pixel 60a and the dummy pixel 60c of the imaging device 203 are the same as those in the imaging device 202. The circuit configuration of the effective pixel 60a is illustrated in FIG. 17A, and the circuit configuration of the dummy pixel 60c thereof is illustrated in FIG. 22.

As illustrated in FIG. 24, in comparison with the imaging device 201 according to the Embodiment 6, the imaging device 203 is different in that the imaging device 203 includes the dummy pixel 60c, which is the same as the one in imaging device 202 according to the Embodiment 7, instead of the dummy pixel 60b. Meanwhile, in comparison with the imaging device 201, the imaging device 203 further includes the voltage average line 43 to connect the charge accumulators 41b of the dummy pixels 60c that belong to the same pixel row, the voltage average switch 29 that controls connection to the voltage average line 43, and the average control line 45 that controls the voltage average switch 29.

Moreover, in comparison with the imaging device 202 according to the Embodiment 7, the imaging device 203 is different in that the imaging device 203 reads both the output signal from the dummy pixel 60c and the output signal from the effective pixel 60a, the effective pixel 60a and the dummy pixel 60c being adjacent to each other, as the respective output signals Vout by using the single vertical signal line 77 as with the imaging device 201 according to the Embodiment 6. In the imaging device 203, the signal outputted from the signal detection transistor 24 of the effective pixel 60a and the signal outputted from the signal detection transistor 24 of the dummy pixel 60c are inputted to the vertical signal line 47. In other words, the output terminal of the address transistor 26 of the effective pixel 60a and the output terminal of the address transistor 26 of the dummy pixel 60c are connected to the common vertical signal line 77. Moreover, in comparison with the imaging device 202, the imaging device 203 is also different in that the imaging device 203 is provided with the two address control lines 46 including the address control line 46a and the address control line 46b corresponding to the same pixel row. Accordingly, the scan signal SELA is applied to the control terminal of the address transistor 26 of the effective pixel 60a through the address control line 46a, and the scan signal SELB is applied to the control terminal of the address transistor 26 of the dummy pixel 60c through the address control line 46b. Thus, the reading operations of the output signals from the effective pixel 60a and the dummy pixel 60c are controlled independently of each other.

As described above, the imaging device 203 has the configuration which is equivalent to a combination of the configuration of the imaging device 201 according to the Embodiment 6 and the configuration of the imaging device 202 according to the Embodiment 7.

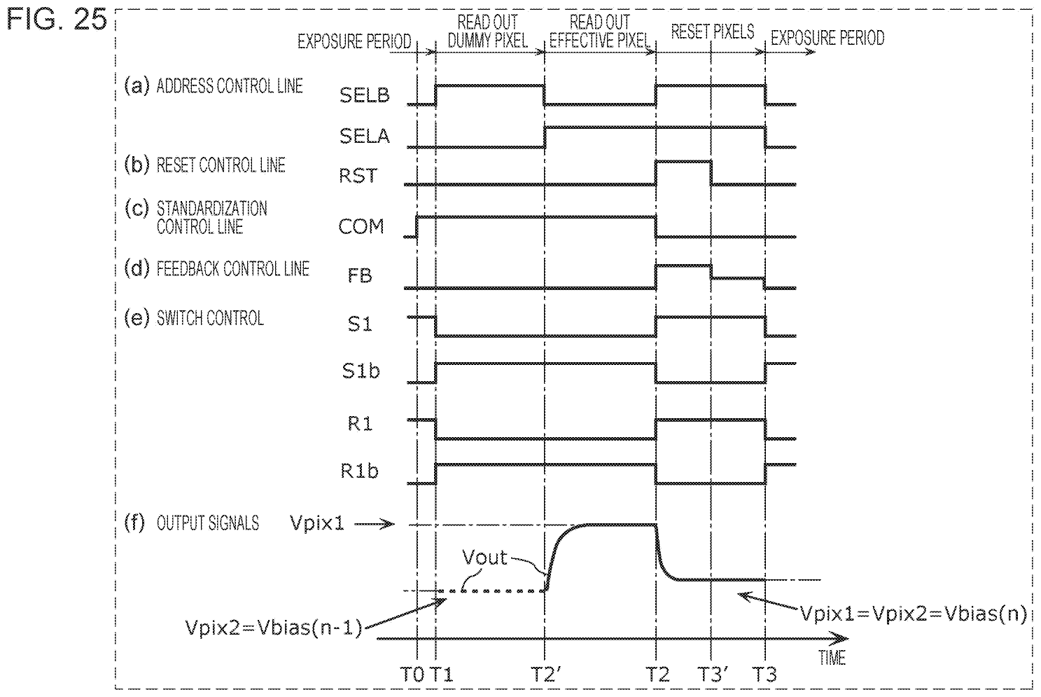

FIG. 25 is a diagram illustrating the sequence of the signal readout operation of the imaging device 203. Graphs in FIGS. 25(a), 25(b), 25(d), 25(e), and 25(f) are the same as the graphs in FIGS. 20(a), 20(b), 20(c), 20(d), and 20(e), respectively. Meanwhile, a graph in FIG. 25(c) is the same as the graph in FIG. 23(c). For this reason, the sequence of the signal readout operation of the imaging device 203 is the same as the descriptions with reference to FIGS. 20 and 23, and explanations will therefore be omitted.

According to the configurations and the signal readout operation as described above, the imaging device 203 can achieve effects of noise reduction and the like, which are equivalent to a combination of the effects described in the Embodiments 1, 2, 3, and 5.

### Other Embodiments

The imaging device according to the present disclosure has been described above based on certain embodiments. However, the present disclosure is not limited to these embodiments.

For example, in the above-described embodiment, the contact plug 54 of the effective pixel 10a and the contact plug 54 of the dummy pixel 10b have the same shape. However, the present disclosure is not limited to this configuration. A plug such as the contact plug to be connected to the gate electrode 24g of the effective pixel 10a may have a thickness, a length, and other dimensions which are different from those of a plug such as the contact plug to be connected to the gate electrode 24g of the dummy pixel 10b. The plug such as the contact plug to be connected to the gate electrode 24g of the effective pixel 10a and the plug such as the contact plug to be connected to the gate electrode 24g of the dummy pixel 10b do not always have to be of the same shape as long as the value of the parasitic capacitance formed between the plug and the peripheral circuit out of the capacitor components constituting the charge accumulator 41a is substantially equal to the value of the parasitic capacitance formed between the plug and the peripheral circuit out of the capacitor components constituting the charge accumulator 41b.

In the meantime, the circuit configurations of the effective pixel and the dummy pixel are not limited to the configurations described in the Embodiments 1 to 8.

For example, in the above-described embodiments, the only difference between the circuit configuration of the effective pixel and the circuit configuration of the dummy pixel lies in whether or not the charge accumulator is electrically connected to the photoelectric conversion layer 15. However, the present disclosure is not limited to this configuration. The circuit configurations of the effective pixel and the dully pixels may be different circuit configurations from each other as long as the respective charge accumulators of the effective pixel and the dummy pixel can receive the same voltage at the time of the resetting operations of the pixels and the parasitic capacitance formed by the plug constituting the charge accumulator, the peripheral lines, and the peripheral circuits of the effective pixel is substantially equal to the parasitic capacitance formed by the plug constituting the charge accumulator, the peripheral lines, and the peripheral circuits of the dummy pixel.

In the above-described embodiments, each effective pixel and the corresponding dummy pixel form the pair of pixels. However, the present disclosure is not limited to this configuration. For example, the number of the dummy pixels may be less than the number of the effective pixels.

Other various modifications to be thought of by those skilled in the art within the range not departing from the gist of the present disclosure are encompassed by the scope of the present disclosure. In addition, the constituents in the two or more embodiments may be combined as appropriate within the range not departing from the gist of the present disclosure.

An imaging device according to the present disclosure can remove noises at high accuracy, and is therefore useful for an imaging device of a laminated type in which a photoelectric conversion layer is provided above a semiconductor substrate, and so forth.

What is claimed is:

1. An imaging device comprising:
a semiconductor substrate;
a photoelectric conversion layer located above the semiconductor substrate;
a first transistor that includes a first gate electrode above the semiconductor substrate and that outputs a signal corresponding to an electric potential of the first gate electrode;
a second transistor that includes a second gate electrode above the semiconductor substrate and that outputs a signal corresponding to an electric potential of the second gate electrode;
a first plug being in contact with the first gate electrode; and
a second plug being in contact with the second gate electrode, wherein
the first gate electrode is electrically connected to the photoelectric conversion layer through the first plug, and
the second gate electrode and the second plug are electrically insulated from the photoelectric conversion layer.

2. The imaging device according to claim 1, further comprising:
a first pixel electrode electrically connected to the photoelectric conversion layer, wherein
the first plug is electrically connected to the photoelectric conversion layer through the first pixel electrode.

3. The imaging device according to claim 2, wherein the first gate electrode and the second gate electrode overlap the first pixel electrode in plan view.

4. The imaging device according to claim 2, further comprising:
a second pixel electrode electrically connected to the photoelectric conversion layer, wherein
the second gate electrode and the second plug are electrically insulated from the second pixel electrode,
the first gate electrode overlaps the first pixel electrode in plan view, and
the second gate electrode overlaps the second pixel electrode in the plan view.

5. The imaging device according to claim 1, further comprising:
at least one plug electrically connected to the second plug, wherein
the at least one plug includes a third plug that is located closest to the photoelectric conversion layer out of the at least one plug, and
a distance between a first surface of the third plug and the photoelectric conversion layer is smaller than a distance between the first surface and the semiconductor substrate, the first surface being a closest surface of the third plug to the photoelectric conversion layer.

6. The imaging device according to claim 1, wherein a length of the first plug is equal to a length of the second plug.

7. The imaging device according to claim 1, further comprising:
a third transistor that includes a third gate electrode above the semiconductor substrate and that outputs a signal corresponding to an electric potential of the third gate electrode;
a fourth transistor that includes a fourth gate electrode above the semiconductor substrate and that outputs a signal corresponding to an electric potential of the fourth gate electrode;
a fourth plug being in contact with the third gate electrode; and
a fifth plug being in contact with the fourth gate electrode, wherein
the third gate electrode is electrically connected to the photoelectric conversion layer through the fourth plug,
the fourth gate electrode and the fifth plug are electrically insulated from the photoelectric conversion layer, and
the second gate electrode is electrically connected to the fourth gate electrode.

8. The imaging device according to claim 7, further comprising:
a first switch coupled between the second gate electrode and the fourth gate electrode.

9. The imaging device according to claim 1, further comprising:
a first signal line to which the signal outputted from the first transistor and the signal outputted from the second transistor are inputted.

10. A method of driving an imaging device that includes a pixel including a charge accumulator to accumulate electric charges obtained by photoelectric conversion by a photoelectric conversion layer and that outputs a signal corresponding to an amount of the electric charges accumulated in the charge accumulator, the method comprising:
resetting an electric potential of the charge accumulator;
accumulating the electric charges in the charge accumulator after the resetting;
reading out a first signal corresponding to the electric potential at the charge accumulator that is reset in the resetting;
reading out a second signal corresponding to the electric potential at the charge accumulator in which the electric charges are accumulated in the accumulating; and
outputting a third signal obtained by subtracting the first signal from the second signal.

11. A method of driving an imaging device that includes which is provided with an effective pixel including a charge accumulator to accumulate electric charges obtained by photoelectric conversion by a photoelectric conversion layer, and a dummy pixel including a dummy charge accumulator being insulated from the photoelectric conversion layer, the method comprising:
resetting an electric potential of the charge accumulator and an electric potential of the dummy charge accumulator;
accumulating the electric charges after the resetting;
reading out a first signal corresponding to the electric potential of the dummy charge accumulator that is reset in the resetting;
reading out a second signal corresponding to the electric potential of the charge accumulator in which the electric charges are accumulated in the accumulating; and
outputting a third signal obtained by subtracting the first signal from the second signal.
